(19) United States
(12) Patent Application Publication
(10) Pub. No.: US 2026/0186594 A1
(43) Pub. Date: Jul. 2, 2026

(54) DISPLAY DEVICE

(71) Applicant: LG Display Co., Ltd., Seoul (KR)

(72) Inventor: Wooram OH, Chilgok-gun (KR)

(73) Assignee: LG Display Co., Ltd., Seoul (KR)

(21) Appl. No.: 19/432,519

(22) Filed: Dec. 24, 2025

(30) Foreign Application Priority Data
Dec. 30, 2024 (KR) 10-2024-0200657

(51) Int. Cl. G06F 3/041; G06F 3/044; G09G 3/3233; H10K 59/40; H10K 59/80

(52) U.S. Cl. CPC G06F 3/0412; H10K 59/40; H10K 59/873; G06F 3/044; G06F 2203/04107; G06F 2203/04111; G06F 2203/04112; G09G 3/3233; G09G 2300/0426; G09G 2320/0233; G09G 2354/00

(57) ABSTRACT

A display device includes: an encapsulation layer and a touch part disposed on the encapsulation layer. The touch part includes variable areas disposed between at least three sub-pixels among a plurality of sub-pixels, fixed areas disposed in each of the variable areas, touch electrodes disposed in an area between the plurality of sub-pixels and the variable areas, and a dummy metal disposed in each of the variable areas. At least one of the touch metal and the dummy metal is disposed in each of the fixed areas. By forming a fixed area in which the metal is fixedly disposed in the variable area in which the touch electrodes are disposed in various patterns, it is possible to alleviate the difference in reflected light due to the difference in pattern shape of the variable area and prevent the touch metal from being visually recognized.

### CROSS-REFERENCE TO RELATED APPLICATIONS

This application claims the benefit of and priority to Korean Patent Application No. 10-2024-0200657 filed on Dec. 30, 2024, in the Korean Intellectual Property Office, the entire contents of which are incorporated herein by reference for all purposes.

### BACKGROUND

### 1. Technical Field

The present disclosure relates to a display device, and particularly to, for example, without limitation, a display device having a built-in touch unit.

### 2. Description of Related Art

An electroluminescent display device is a self-luminous display device. Unlike a liquid crystal display device, the electroluminescent display device does not require a separate light source and can be manufactured in lightweight, thin designs. Furthermore, the electroluminescent display device is advantageous in terms of power consumption due to low-voltage operation, has excellent color expression, response speed, viewing angle, and contrast ratio (CR), and is being studied as next-generation displays.

Among the electroluminescent display devices, there are touchscreen-integrated display devices that include a touch unit capable of recognizing the user's touch. The touchscreen-integrated display devices allow direct input of information using a finger or pen, and are widely used in navigation systems, portable terminals, and home appliances.

The description of related art should not be considered prior art merely because it is mentioned in or associated with this section. The description of related art includes information that describes one or more aspects of the subject technology, and the description in this section does not limit the scope of the present disclosure.

### SUMMARY

An aspect of the present disclosure provides a display device having a built-in touch unit.

Another aspect of the present disclosure provides a display device with improved performance of a touch unit.

Still another aspect of the present disclosure provides a display device that reduces electromagnetic interference of a touch unit.

Still another aspect of the present disclosure provides a display device that suppresses disconnection of the line in the area of a dam member.

Still another aspect of the present disclosure provides a display device with reduced capacitance variation in a touch line.

Still another aspect of the present disclosure provides a display device having improved touch sensing performance by forming a dummy touch electrode between a plurality of touch electrodes.

Still another aspect of the present disclosure provides a display device that minimizes the transmission delay of touch signals.

Still another aspect of the present disclosure provides a display device in which a metal of a touch part is not visible.

Still another aspect of the present disclosure provides a display device in which a deviation of reflected light caused by a touch electrode and a spacer in each of a plurality of variable areas is reduced to minimize visibility of the touch electrode.

Aspects of the present disclosure are not limited to the above-mentioned aspects, and other aspects, which are not mentioned above, can be clearly understood by those skilled in the art from the following descriptions.

A display device according to an example embodiment of the present disclosure includes: a substrate; a plurality of sub-pixels; an encapsulation layer disposed on the substrate; and a touch part disposed on the encapsulation layer, the touch part includes: a plurality of variable areas disposed between at least three sub-pixels among the plurality of sub-pixels; a plurality of fixed areas disposed in each of the plurality of variable areas; a plurality of touch electrodes disposed in each of the plurality of areas between the plurality of sub-pixels and the plurality of variable areas and composed of touch metals; and a dummy metal disposed in each of the plurality of variable areas, wherein at least one of the touch metal and the dummy metal is disposed in each of the plurality of fixed areas. By forming a fixed area in which the metal is fixedly disposed in the variable area in which the touch electrodes are disposed in various patterns, it is possible to alleviate the difference in reflected light due to the difference in pattern shape of the variable area and prevent the touch metal from being visually recognized.

A display device according to another example embodiment of the present disclosure includes: a substrate; a display area and a non-display area; a planarization layer disposed on the substrate; a light emitting element disposed on the planarization layer; an encapsulation layer disposed on the light emitting element and having an edge disposed in the non-display area; and a touch part disposed on the encapsulation layer and the substrate, the touch part includes: a touch buffer layer on the encapsulation layer; and a touch insulating layer on the touch buffer layer, and the touch buffer layer and the touch insulating layer may extend to an area outside the encapsulation layer to cover the edge of the encapsulation layer. Accordingly, a display device capable of touch sensing may be implemented by directly forming a touch part on the encapsulation layer.

Other detailed matters of the example embodiments are included in the detailed description and the drawings.

According to one or more aspects of the present disclosure, a display device having a built-in touch unit can be provided.

According to one or more aspects of the present disclosure, a display device with improved performance of a touch unit can be provided.

According to one or more aspects of the present disclosure, the electromagnetic interference in the touch unit can be reduced by including a pseudo line.

According to one or more aspects of the present disclosure, it is possible to suppress disconnection of the touch line over a dam member.

According to one or more aspects of the present disclosure, capacitance variation in the touch line can be reduced by varying the width of the touch line.

According to one or more aspects of the present disclosure, touch sensing performance can be reduced by forming a dummy touch electrode between the plurality of touch electrodes.

According to one or more aspects of the present disclosure, the transmission delay of the touch signal can be minimized.

According to one or more aspects of the present disclosure, the metal pattern of the fixed area is commonly disposed in the variable area between the plurality of sub-pixels so that the metal pattern of the touch part is not visually recognized.

According to one or more aspects of the present disclosure, it is possible to reduce the deviation of reflected light due to the touch electrode and the spacer in each of the plurality of variable areas.

The effects according to one or more aspects of the present disclosure are not limited to the contents described above, and more various effects are included in the present disclosure.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a schematic diagram of a display device according to an example embodiment of the present disclosure;

FIG. 2 is a schematic plan view of the display device according to an example embodiment of the present disclosure;

FIG. 3 is a cross-sectional view of a sub-pixel of the display device according to an example embodiment of the present disclosure;

FIG. 4 is an enlarged plan view of an area A1 of FIG. 2;

FIG. 5A is a cross-sectional view taken along line A-A′ of FIG. 2;

FIG. 5B is a cross-sectional view taken along line B-B′ of FIG. 2;

FIGS. 6A to 6C are schematic cross-sectional views of a dam member of the display device according to an example embodiment of the present disclosure;

FIG. 7 is an enlarged plan view of an area A2 of FIG. 2;

FIGS. 8 and 9 are schematic plan views of a touch unit of the display device according to an example embodiment of the present disclosure;

FIG. 10 is a schematic enlarged plan view of the touch unit of the display device according to an example embodiment of the present disclosure;

FIGS. 11 and 12 are schematic enlarged plan views of the touch unit of the display device according to an example embodiment of the present disclosure;

FIG. 13 is a schematic plan view of a display device according to an example embodiment of the present disclosure;

FIGS. 14 and 15 are enlarged plan views of an area A3 of FIG. 13;

FIG. 16 is an enlarged plan view of an area A4 of FIG. 14;

FIG. 17 is a cross-sectional view taken along line C-C′ of FIG. 16;

FIG. 18 is an enlarged plan view of an area A5 of FIG. 16;

FIG. 19 is an enlarged plan view of an area A6 of FIG. 13;

FIG. 20 is a cross-sectional view taken along line D-D′ of FIG. 19;

FIG. 21 is an enlarged plan view of an area A7 of FIG. 14;

FIG. 22A is an enlarged plan view of an area A8 of FIG. 14;

FIG. 22B is a cross-sectional view taken along line E-E′ of FIG. 22A;

FIG. 23A is an enlarged plan view of an area A8 of FIG. 14;

FIG. 23B is a cross-sectional view taken along line F-F′ of FIG. 23A;

FIG. 24 is a schematic enlarged plan view of a display device according to another example embodiment of the present disclosure.

FIG. 25 is an enlarged plan view of a plurality of variable areas of a touch part of a display device according to another example embodiment of the present disclosure.

FIGS. 26A and 26B are enlarged plan views for explaining a fixed area of a touch part of a display device according to another example embodiment of the present disclosure.

FIGS. 27A to 27D are schematic cross-sectional views of a touch part of a display device according to another example embodiment of the present disclosure.

FIG. 28 is a schematic enlarged plan view of a display device according to still another example embodiment of the present disclosure.

FIG. 29A is an enlarged plan view of an area A9 of FIG. 28.

FIG. 29B is an enlarged plan view of an area A10 of FIG. 28.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including”, “having”, and “consist of” used herein are generally intended to allow other components to be added unless the terms are used with the term “only”. Any references to singular may include plural unless expressly stated otherwise. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used to refer to one element separately from another. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

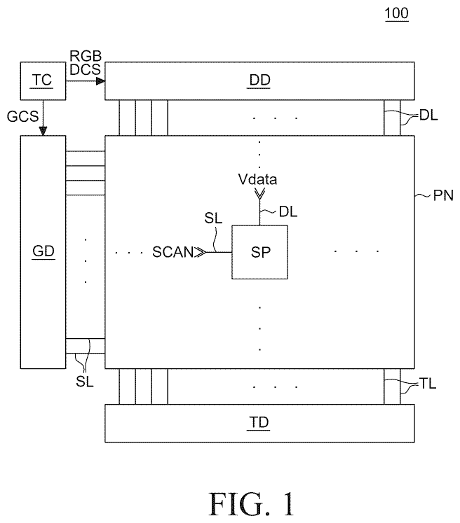

FIG. 1 is a schematic diagram of a display device according to one embodiment of the present disclosure. For convenience of explanation, in FIG. 1, only a display panel PN, a gate driver GD, a data driver DD, a touch driver TD, and a timing controller TC among the various components of a display device 100 are illustrated.

Referring to FIG. 1, the display device 100 includes the display panel PN including a plurality of sub-pixels SP, the gate driver GD and the data driver DD that supply various signals to the display panel PN, the timing controller TC that controls the gate driver GD and the data driver DD, and the touch driver TD for sensing a touch input.

The display panel PN is configured to display images to a user and includes the plurality of sub-pixels SP. In the display panel PN, a plurality of scan lines SL and a plurality of data lines DL intersect each other, and each of the plurality of sub-pixels SP is connected to the scan line SL and the data line DL. In addition, although not illustrated in the drawings, each of the plurality of sub-pixels SP may be connected to a high-potential power line, a low-potential power line, a reference line, or the like.

The plurality of sub-pixels SP is the minimum units that constitute a screen, and each of the plurality of sub-pixels SP includes a light-emitting diode and a pixel circuit for driving the light-emitting diode. The plurality of light-emitting diodes may be defined differently depending on the type of the display device 100. For example, when the display device 100 is an organic light-emitting display device 100, the light-emitting diode may be an organic light-emitting diode (OLED).

The gate driver GD supplies a plurality of scan signals SCAN to the plurality of scan lines SL according to a plurality of gate control signals GCS provided from the timing controller TC. In FIG. 1, one gate driver GD is illustrated as being spaced apart from one side of the display panel PN, but the number and disposition of the gate drivers GD are not limited thereto.

The data driver DD converts image data RGB transmitted from the timing controller TC into data voltage Vdata using a reference gamma voltage according to a plurality of data control signals DCS provided from the timing controller TC. The data driver DD may supply the converted data voltage Vdata to the plurality of data lines DL.

The timing controller TC aligns the image data RGB input from the outside and supplies the image data RGB to the data driver DD. The timing controller TC may generate the gate control signal GCS and the data control signal DCS using externally input synchronization signals, such as a dot clock signal, a data enable signal, and a horizontal/vertical synchronization signal. In addition, the timing controller TC may control the gate driver GD and the data driver DD by supplying the generated gate control signal GCS and data control signal DCS to the gate driver GD and the data driver DD, respectively.

The touch driver TD drives a touch unit 150 during a touch sensing period based on a touch enable signal input from the timing controller TC or the external component. The touch driver TD may sense a touch input based on a signal from the touch unit 150.

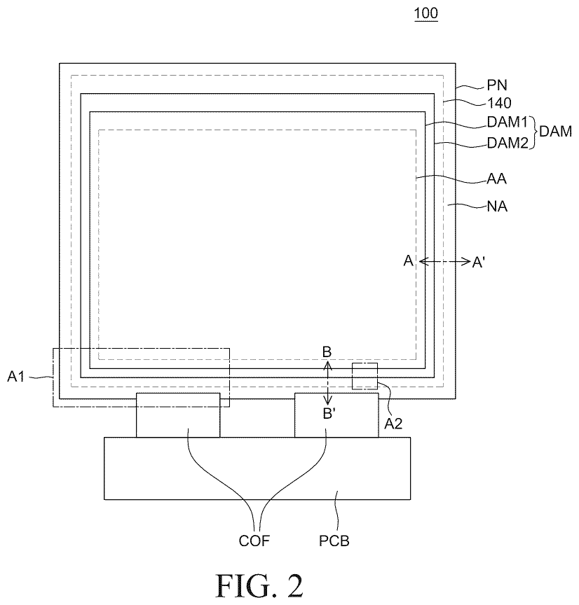

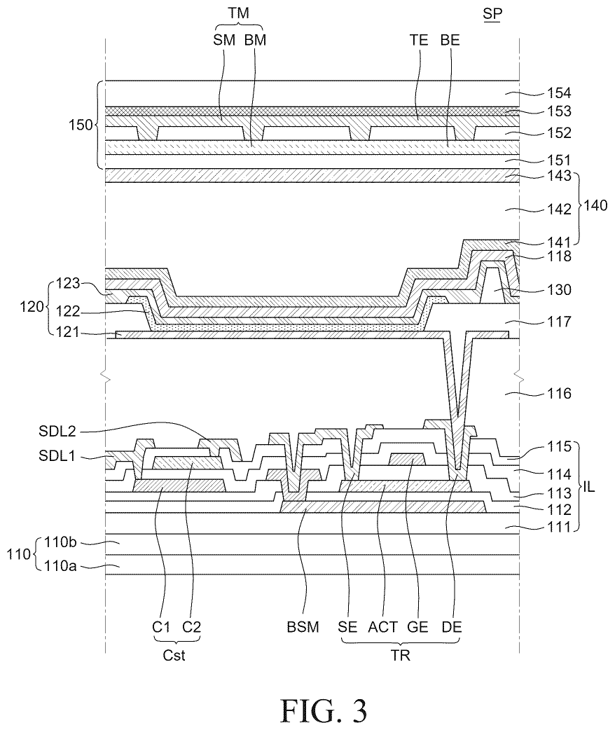

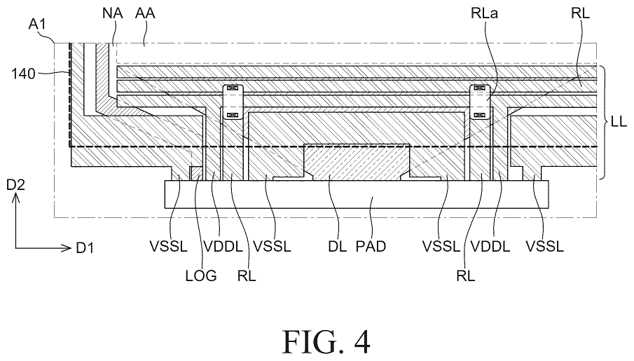

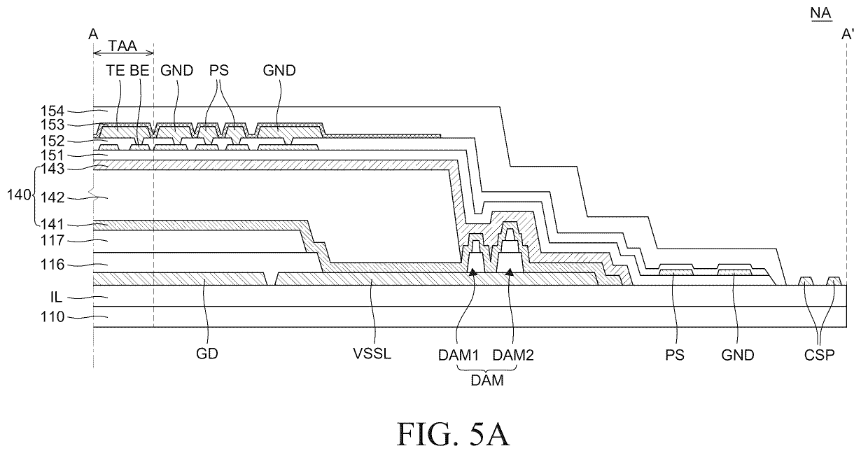

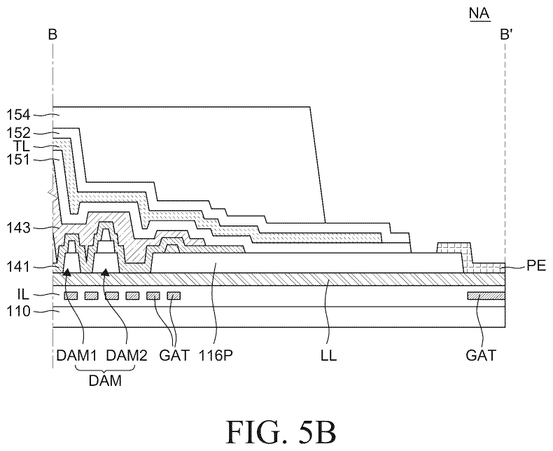

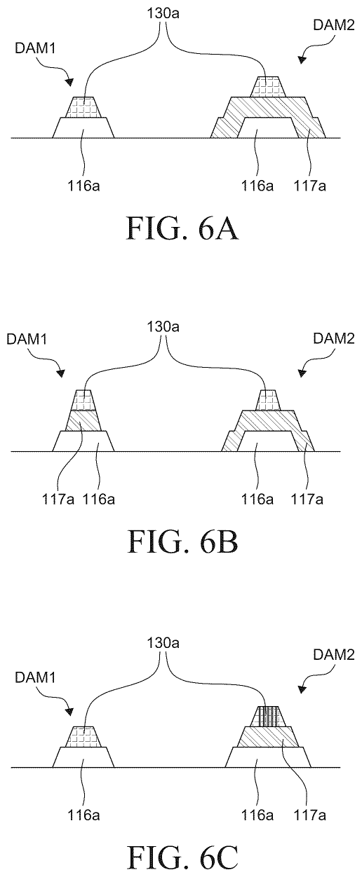

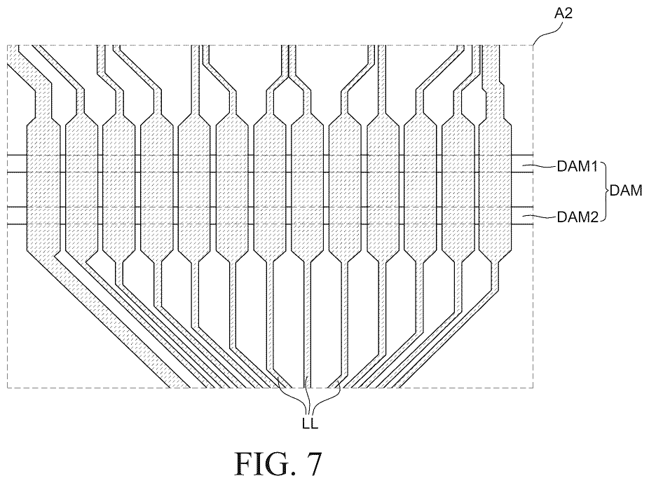

FIG. 2 is a schematic plan view of the display device according to an example embodiment of the present disclosure. FIG. 3 is a cross-sectional view of a sub-pixel of the display device according to an example embodiment of the present disclosure. FIG. 4 is an enlarged plan view of an area A1 of FIG. 2. FIG. 5A is a cross-sectional view taken along line A-A′ of FIG. 2. FIG. 5B is a cross-sectional view taken along line B-B′ of FIG. 2. FIGS. 6A to 6C are schematic cross-sectional views of a dam member of a display device according to an example embodiment of the present disclosure. FIG. 7 is an enlarged plan view of an area A2 of FIG. 2. For convenience of explanation, only a low-potential power line VSSL, a high-potential power line VDDL, a reference line RL, a LOG (Line On Glass) line LOG, and a data line DL among a plurality of lines are illustrated in FIG. 4.

Referring to FIG. 2, the display panel PN of the display device 100 includes a display area AA and a non-display area NA. The display area AA may be an area where an image is displayed. The plurality of sub-pixels SP may be formed in the display area AA to display an image. The non-display area NA may be an area where an image is not displayed. Various lines and circuits for driving the plurality of sub-pixels SP of the display area AA may be disposed in the non-display area NA. For example, the gate driver GD may be mounted in the non-display area NA, or a pad unit PAD on which a flexible film COF and a printed circuit board PCB are bonded may be disposed in the non-display area NA. In addition, wiring lines for driving the plurality of sub-pixels SP, the gate driver GD, the touch unit 150, or the like may be disposed in the non-display area NA.

A plurality of flexible films COF is connected to the pad unit PAD of the display panel PN. The plurality of flexible films COF may be a film in which various components are disposed on a flexible base film. For example, a driving integrated circuit (IC) may be disposed on the plurality of flexible films COF. The driving IC may be a component that processes data and driving signals for displaying an image. The plurality of flexible films COF may be attached or bonded to a plurality of driving pad electrodes PE via a conductive adhesive layer, but the embodiments of the present disclosure are not limited thereto.

The printed circuit board PCB is connected to a plurality of flexible films COF. The printed circuit board PCB is electrically connected to the flexible films COF and may be a component that supplies signals to a driving IC. Various components for supplying various signals to the driving ICs may be disposed on the printed circuit board PCB. For example, various components such as the timing controller TC, a power management integrated circuit (PMIC), a memory, or a processor may be disposed on the printed circuit board PCB, but the embodiments of the present disclosure are not limited thereto.

Referring to FIG. 3, the substrate 110 is a support member for supporting other components of the display device 100 and may be made of an insulating material. For example, the substrate 110 may be made of glass, resin, or the like.

The substrate 110 may be formed of one or more layers. For example, the substrate 110 may be formed of a bilayer structure including a first substrate 110a and a second substrate 110b on the first substrate 110a. For example, the first substrate 110a and the second substrate 110b may be formed of polyimide (PI). In addition, although not illustrated in the drawing, an insulating layer may be further disposed between the first substrate 110a and the second substrate 110b.

A multi-buffer layer 111 is disposed on a substrate 110. The multi-buffer layer 111 may reduce the penetration of moisture or impurities through the substrate 110. For example, the multi-buffer layer 111 may be composed of a single layer or a plurality of layers of an insulating material such as silicon nitride (SiNx), silicon oxide (SiOx), and silicon oxynitride (SiON), but is not limited thereto.

A light-shielding layer BSM is disposed on the multi-buffer layer 111. The light-shielding layer BSM may minimize leakage current of a plurality of transistors TR by blocking light incident on an active layer ACT of a transistor TR from the lower portion of the substrate 110. In addition, the light-shielding layer BSM may minimize damage to the plurality of transistors TR caused by charges trapped in the substrate 110. The light-shielding layer BSM may be connected to a source electrode SE or a drain electrode DE of the transistor TR so as to minimize its influence on a threshold voltage of the transistor TR. The light-shielding layer BSM may be formed as a single layer or a plurality of layers made of, for example, one of molybdenum (Mo), copper (Cu), titanium (Ti), aluminum (Al), chromium (Cr), gold (Au), nickel (Ni), and neodymium (Nd), or an alloy thereof, but is not limited thereto.

An active buffer layer 112 is disposed on the light-shielding layer BSM. The active buffer layer 112 may protect the transistor TR from impurities such as alkali ions leaking from the substrate 110. In addition, the active buffer layer 112 may improve adhesion between layers formed above the active buffer layer 112 and the substrate 110. For example, the active buffer layer 112 may be formed of a single layer or a plurality of layers of an insulating material such as silicon nitride (SiNx), silicon oxide (SiOx), and silicon oxynitride (SiON), but is not limited thereto.

The transistor TR is disposed on the active buffer layer 112. The transistor TR includes the active layer ACT, a gate electrode GE, the source electrode SE, and the drain electrode DE.

First, the active layer ACT is disposed on the active buffer layer 112. The active layer ACT may be made of a semiconductor material such as an oxide semiconductor, amorphous silicon, or polysilicon, but is not limited thereto.

A gate insulating layer 113 is disposed on the active layer ACT. The gate insulating layer 113 is an insulating layer for insulating the active layer ACT and the gate electrode GE, and may be composed of a single layer or a plurality of layers of silicon oxide (SiOx) or silicon nitride (SiNx), but is not limited thereto.

The gate electrode GE is disposed on the gate insulating layer 113. The gate electrode GE may be a single layer or a plurality of layers made of a conductive material, for example, one of molybdenum (Mo), aluminum (Al), chromium (Cr), gold (Au), titanium (Ti), nickel (Ni), neodymium (Nd), and copper (Cu), or an alloy thereof, but is not limited thereto.

A first interlayer insulating layer 114 is disposed on the gate electrode GE, and a second interlayer insulating layer 115 is disposed on the first interlayer insulating layer 114. The first interlayer insulating layer 114 and the second interlayer insulating layer 115 are insulating layers for protecting the underlying structure, and may be composed of a single layer or a plurality of layers of silicon oxide (SiOx) or silicon nitride (SiNx), but are not limited thereto.

The source electrode SE and the drain electrode DE are disposed on the second interlayer insulating layer 115. The source electrode SE and the drain electrode DE can be electrically connected to the active layer ACT through contact holes formed in the second interlayer insulating layer 115, the first interlayer insulating layer 114, and the gate insulating layer 113. The source electrode SE and the drain electrode DE may be formed of a single layer or multilayer structure of a conductive material, for example, copper (Cu), aluminum (Al), molybdenum (Mo), nickel (Ni), titanium (Ti), gold (Au), chromium (Cr), or an alloy thereof, but are not limited thereto.

A capacitor Cst is disposed on the gate insulating layer 113. The capacitor Cst may include a first capacitor electrode C1 and a second capacitor electrode C2. The first capacitor electrode C1 may be disposed on the gate insulating layer 113, and the second capacitor electrode C2 may be disposed on the first interlayer insulating layer 114. The first capacitor electrode C1 and the second capacitor electrode C2 may overlap each other with the first interlayer insulating layer 114 interposed therebetween. For example, the first capacitor electrode C1 and the second capacitor electrode C2 may be a single layer or plurality of layers made of any one of molybdenum (Mo), aluminum (Al), chromium (Cr), gold (Au), titanium (Ti), nickel (Ni), neodymium (Nd), and copper (Cu), or an alloy thereof, but is not limited thereto.

Meanwhile, various conductive layers may be further disposed on the substrate 110. The various conductive layers may constitute any one of a plurality of wiring lines, a plurality of transistors TR, and a plurality of capacitors Cst. For example, a first source-drain conductive layer SDL1 and a second source-drain conductive layer SDL2 may be disposed on the second interlayer insulating layer 115. The first source-drain conductive layer SDL1 may be connected to the first capacitor electrode C1, and the second source-drain conductive layer SDL2 may be connected to the second capacitor electrode C2. Each of the first source-drain conductive layer SDL1 and the second source-drain conductive layer SDL2 may function as an electrode that connects the first capacitor electrode C1 and the second capacitor electrode C2 to other components of the sub-pixel SP.

A planarization layer 116 is disposed on the transistor TR. The planarization layer 116 is an insulating layer that planarizes the underlying structure on the substrate 110. The planarization layer 116 may be made of an organic material, and may be composed of a single layer or plurality of layers of an organic material such as polyimide or photo acryl, but is not limited thereto.

A light-emitting diode 120 is disposed on the planarization layer 116. The light-emitting diode 120 may be an organic light-emitting diode (OLED). The light-emitting diode 120 includes an anode 121, a light-emitting layer 122, and a cathode 123.

The anode 121 is disposed on the planarization layer 116. The anode 121 may be connected to the drain electrode DE of the transistor TR. The anode 121 may be formed of a conductive material having a high work function to supply holes to the light-emitting layer 122. For example, the anode 121 may be formed of a transparent conductive material such as indium tin oxide (ITO), or indium zinc oxide (IZO), but is not limited thereto.

Meanwhile, the display device 100 may be implemented in a top emission or bottom emission manner. In the case of the top emission manner, a reflective layer may be disposed below the anode 121 to reflect light emitted from the light-emitting layer 122 toward the cathode 123. For example, the reflective layer may include a material with excellent reflectivity, such as aluminum (Al) or silver (Ag), but is not limited thereto. Conversely, in the case of the bottom emission manner, the anode 121 may be formed only of a transparent conductive material. Hereinafter, the display device 100 according to an example embodiment of the present disclosure will be described assuming that the display device 100 is implemented in the top emission manner.

A bank 117 is disposed on the anode 121 and the planarization layer 116. The bank 117 may cover the edge of the anode 121. The bank 117 may partition the plurality of sub-pixels SP and suppress color mixing between the plurality of sub-pixels SP. The bank 117 may be an organic insulating material. For example, the bank 117 may be made of any one of polyimide, acrylic, and benzocyclobutene (BCB)-based resins, but is not limited thereto.

A spacer 130 is disposed on the bank 117. The spacer 130 may suppress damage to the light-emitting diode 120 that may occur when a fine metal mask (FMM) used to form the light-emitting layer 122 of the light-emitting diode 120 directly contacts the bank 117 or the anode 121. The spacer 130 may be made of the same material as the bank 117 or may be made of an insulating material different from the bank 117, but is not limited thereto. In addition, the spacer 130 and the bank 117 may be formed integrally at once. Since the spacer 130 is disposed on the bank 117, the cathode 123 may be disposed to cover the spacer 130 and the bank 117.

The light-emitting layer 122 is disposed on the anode 121 and the bank 117. The light-emitting layer 122 may be an organic layer for emitting light of a specific color. The light-emitting layer 122 may further include various layers such as a hole transport layer, a hole injection layer, a hole blocking layer, an electron injection layer, an electron blocking layer, or an electron transport layer. The light-emitting layer 122 may be separately formed for each sub-pixel SP so that each sub-pixel SP may emit light of a different color. For example, the light-emitting layer 122 for red, the light-emitting layer 122 for green, and the light-emitting layer 122 for blue may be separately formed for each sub-pixel SP. Meanwhile, the light-emitting layer 122 for emitting white light may be commonly formed for the plurality of sub-pixels SP, and a light conversion member for converting the white light into light of various colors may be separately provided, but the embodiments of the present disclosure are not limited thereto.

The cathode 123 is disposed on the light-emitting layer 122. The cathode 123 may be formed as a single layer across the entire surface of the substrate 110. That is, the cathode 123 may be a common layer formed in common for the plurality of sub-pixels SP. Since the cathode 123 supplies electrons to the light-emitting layer 122, the cathode 123 may be formed of a conductive material having a low work function. The cathode 123 may be formed of, for example, a transparent conductive material such as indium tin oxide (ITO) or indium zinc oxide (IZO), a metal alloy such as MgAg, an ytterbium (Yb) alloy, or the like, and may further include a metal doping layer, but is not limited thereto.

A protective layer 118 is disposed on the cathode 123. The protective layer 118 may protect the light-emitting diode 120 from foreign substances or moisture infiltration. For example, the protective layer 118 may be made of an inorganic material such as aluminum oxide (Al2O3) or silicon nitride (SiNx).

An encapsulation layer 140 is disposed on the protective layer 118. The encapsulation layer 140 may protect the light-emitting diode 120 from moisture or the like penetrating from the outside of the display device 100. The encapsulation layer 140 includes a first inorganic encapsulation layer 141, an organic encapsulation layer 142, and a second inorganic encapsulation layer 143.

The first inorganic encapsulation layer 141 is disposed on the protective layer 118, and the second inorganic encapsulation layer 143 is disposed on the first inorganic encapsulation layer 141. The first inorganic encapsulation layer 141 and the second inorganic encapsulation layer 143 may serve to block the penetration of moisture or oxygen. The first inorganic encapsulation layer 141 and the second inorganic encapsulation layer 143 may be made of an inorganic material, and for example, may be made of an inorganic material such as silicon nitride (SiNx), silicon oxide (SiOx), or aluminum oxide (AlOx), but are not limited thereto.

The organic encapsulation layer 142 is disposed between the first inorganic encapsulation layer 141 and the second inorganic encapsulation layer 143. The organic encapsulation layer 142 may be formed to have a thickness thicker than the first inorganic encapsulation layer 141 and the second inorganic encapsulation layer 143 so as to adsorb and block foreign substances (particles) that may occur during the manufacturing process of the display device 100. The organic encapsulation layer 142 may fill cracks that may occur in the first inorganic encapsulation layer 141 and the second inorganic encapsulation layer 143, and cover foreign substances on the first inorganic encapsulation layer 141 to flatten the underlying structure. The organic encapsulation layer 142 may be made of an organic material, and may be made of, for example, an epoxy-based polymer or an acrylic-based polymer, but is not limited thereto.

The touch unit 150 is disposed on the encapsulation layer 140. The touch unit 150 may sense an external touch input using a user's finger or a touch pen, or the like. The touch unit 150 includes a touch buffer layer 151, a bridge electrode BE, a touch electrode TE, a touch insulation layer 152, a touch passivation layer 153, and a touch protection layer 154.

First, the touch buffer layer 151 is disposed on the encapsulation layer 140. The touch buffer layer 151 is an insulating layer for protecting peripheral components such as the encapsulation layer 140 and the light-emitting diode 120 during the formation process of the touch unit 150. The touch buffer layer 151 may minimize the penetration of moisture from the outside, materials used in the manufacturing process of the touch unit 150, or the like into the light-emitting diode 120. For example, the touch buffer layer 151 may be made of an insulating material such as silicon oxide (SiOx) or silicon nitride (SiNx), but is not limited thereto.

A plurality of bridge electrodes BE are disposed on a touch buffer layer 151. The plurality of bridge electrodes BE is electrodes made of a bridge metal BM and may connect a plurality of touch electrodes TE to each other. For example, a pair of adjacent touch electrodes TE among the plurality of touch electrodes TE may be electrically connected to each other through the bridge electrodes BE. For example, the plurality of bridge electrodes BE may be formed of a metal material such as copper (Cu), aluminum (Al), titanium (Ti), chromium (Cr), nickel (Ni), or a laminated structure of a metal material such as titanium/aluminum/titanium (Ti/Al/Ti), but is not limited thereto.

The touch insulation layer 152 is disposed on the bridge electrode BE. The touch insulation layer 152 is disposed between the plurality of bridge electrodes BE and the plurality of touch electrodes TE, and may insulate some of the bridge electrodes BE and some of the touch electrodes TE. The touch insulation layer 152 may be made of an insulating material such as silicon oxide (SiOx) or silicon nitride (SiNx), but is not limited thereto.

The plurality of touch electrodes TE is disposed on a touch insulation layer 152. The plurality of touch electrodes TE is electrodes made of a sensor metal SM and are electrodes for sensing a touch input. For example, when the touch unit 150 senses a touch input in a mutual capacitance manner, the plurality of touch electrodes TE may be made of a touch driving electrode to which a touch driving signal is applied and a touch sensing electrode that forms a capacitance with the touch driving electrode. In addition, the touch input may be sensed based on a change in capacitance between the touch driving electrode and the touch sensing electrode.

However, the touch sensing method of the touch unit 150 is an example, and the touch unit 150 may sense touch input using a self-capacitance method, but is not limited thereto.

The touch passivation layer 153 is disposed on the plurality of touch electrodes TE. The touch passivation layer 153 is an insulating layer for protecting the plurality of touch electrodes TE and the plurality of bridge electrodes BE, and can suppress corrosion of the plurality of touch electrodes TE and the plurality of bridge electrodes BE caused by external moisture, or the like. For example, the touch passivation layer 153 may be made of an insulating material such as silicon oxide (SiOx) or silicon nitride (SiNx), but is not limited thereto.

The touch protection layer 154 is disposed on the touch passivation layer 153. The touch protection layer 154 may protect the plurality of touch electrodes TE and the plurality of bridge electrodes BE from external moisture or impact together with the touch passivation layer 153. For example, the touch protection layer 154 may be made of an organic material such as an epoxy-based or acrylic-based polymer, but is not limited thereto.

Meanwhile, in the drawing, the touch passivation layer 153 is depicted as being disposed below the touch protection layer 154, but the touch passivation layer 153 may also be formed on the touch protection layer 154, and is not limited thereto.

Referring to FIG. 4, the pad unit PAD and the plurality of wiring lines are disposed in the non-display area NA.

The pad unit PAD is a portion electrically connected to a plurality of flexible films COF, and may include a plurality of driving pad electrodes PE and a plurality of touch pad electrodes TPE. Each of the plurality of driving pad electrodes PE may transmit signals from the printed circuit board PCB and the flexible film COF to various wiring lines of the display panel PN. In addition, the plurality of touch pad electrodes TPE may transmit signals from the printed circuit board PCB and the flexible film COF to the touch line TL of the touch unit 150. The pad unit PAD may be exposed from the encapsulation layer 140 for connection with the flexible film COF. The pad unit PAD may be disposed on the outside of the encapsulation layer 140.

Wiring lines related to driving the display device 100, that is, image display, are disposed in the non-display area NA. For example, a plurality of low-potential power lines VSSL, a LOG (Line On Glass) line LOG, a plurality of high-potential power lines VDDL, a plurality of reference lines RL, and a plurality of data lines DL may be disposed in the non-display area NA.

The plurality of low-potential power lines VSSL is disposed in the non-display area NA. The plurality of low-potential power lines VSSL is lines for applying a low-potential power voltage to the plurality of sub-pixels SP. Some of the plurality of low-potential power lines VSSL extending from the pad unit PAD may extend in a form that encloses the periphery of the display area AA. In addition, other of the plurality of low-potential power lines VSSL extending from the pad unit PAD may be disposed to cover the data lines DL, thereby functioning as a protective film to suppress influences of the data lines DL on other lines.

The plurality of high-potential power lines VDDL is disposed in the non-display area NA. The plurality of high-potential power lines VDDL is wiring lines for applying a high-potential power voltage to the plurality of sub-pixels SP. The shorting-bar-shaped high-potential power line VDDL extending in a first direction D1 between the display area AA and the pad unit PAD is disposed. Moreover, the plurality of high-potential power lines VDDL extending in a second direction D2 from the pad unit PAD may be connected to the shorting-bar-shaped high-potential power line VDDL. In this case, a portion of the plurality of high-potential power lines VDDL extending in the second direction D2 from the pad unit PAD may be disposed between the plurality of low-potential power lines VSSL. Therefore, by forming the shorting bar-shaped high-potential power line VDDL that connects the plurality of high-potential power lines VDDL in the non-display area NA, the resistance deviation between the plurality of high-potential power lines VDDL can be reduced and the brightness uniformity can be improved.

In the non-display area NA, the reference line RL is disposed between the high-potential power line VDDL and the low-potential power line VSSL. A shorting-bar-shaped reference line RL extending in the first direction D1 between the display area AA and the pad unit PAD may be disposed, and a plurality of reference lines RL extending in a second direction D2 from the pad unit PAD may be connected to the shorting-bar-shaped reference line RL. At this time, the high-potential power line VDDL on the same layer as the reference line RL is disposed between the shorting-bar-shaped reference line RL and the reference line RL connected to the pad unit PAD. Accordingly, at the point where the reference line RL and the high-potential power line VDDL intersect each other, an auxiliary reference line RLa located on a different layer from the high-potential power line VDDL may be used to connect the shorting-bar-shaped reference line RL and the reference line RL connected to the pad unit PAD. Therefore, by forming the shorting-bar-shaped reference line RL that connects the plurality of reference lines RL in the non-display area NA, the resistance deviation between the plurality of reference lines RL can be reduced and the brightness uniformity can be improved.

In the non-display area NA, the LOG line LOG is disposed between the low-potential power line VSSL and the high-potential power line VDDL. The LOG line LOG is a wiring line for transmitting various signals to the gate driver GD. For example, the gate driver GD is mounted in the non-display area NA, and the LOG line LOG extends from the pad unit PAD to the gate driver GD to transmit various signals to the gate driver GD.

The plurality of data lines DL may be disposed to extend from the pad unit PAD. The plurality of data lines DL may be disposed to radially extend from the pad unit PAD. The plurality of data lines DL may extend from the pad unit PAD to the display area AA, thereby transmitting the data voltage Vdata to the plurality of sub-pixels SP of the display area AA.

Meanwhile, a multiplexer circuit MUX, an electrostatic discharge protection circuit ESD, and a light inspection transistor AP may be further disposed between the shorting-bar-shaped reference line RL and the display area AA. The multiplexer circuit MUX is a circuit for distributing a signal to the plurality of wiring lines, and the output of each wiring line may be controlled using the multiplexer circuit MUX. The electrostatic discharge protection circuit ESD may protect the internal configuration of the display device 100 by discharging static electricity introduced from the outside. When checking whether the light-emitting diode 120 is turned on in the manufacturing process of the display device 100, a signal may be temporarily applied to the light-emitting diode 120 using the light inspection transistor AP.

Meanwhile, the wiring lines disposed between the pad unit PAD and the display area AA may also be referred to as link lines LL. That is, some of the wiring lines disposed in the non-display area NA may be defined as the link lines LL. For example, in order to distinguish between some of the data lines DL disposed in the display area AA and the remainder of the data lines DL disposed in the non-display area NA, the remainder of the data lines DL disposed in the non-display area NA may be referred to as data link lines LL. Similarly, some of the high-potential power lines VDDL, low-potential power lines VSSL, and reference lines RL disposed in the non-display area NA may also be referred to as high-potential power link lines LL, low-potential power link lines LL, reference link lines LL, or the like. Therefore, the following description will assume that the link lines LL define some of the wiring lines disposed in the non-display area NA.

Next, referring to FIG. 3 and FIG. 5A together, some configurations of the display area AA may be disposed to extend to the non-display area NA.

Meanwhile, in FIG. 5A, for convenience of explanation, the multi-buffer layer 111, the active buffer layer 112, the gate insulating layer 113, the first interlayer insulating layer 114, and the second interlayer insulating layer 115 are briefly represented as an insulating layer group IL. However, in reality, the multi-buffer layer 111, the active buffer layer 112, the gate insulating layer 113, the first interlayer insulating layer 114, and the second interlayer insulating layer 115 may be disposed between the substrate 110 and the low-potential power line VSSL.

The encapsulation layer 140 may be disposed to cover the entire display area AA and a portion of the non-display area NA extending from the display area AA. For example, the organic encapsulation layer 142 of the encapsulation layer 140 may be disposed from the display area AA to an area a dam member DAM in the non-display area NA. Moreover, the first inorganic encapsulation layer 141 and the second inorganic encapsulation layer 143 may extend to an area outside the dam member DAM. The first inorganic encapsulation layer 141 and the second inorganic encapsulation layer 143 extending to the area outside the dam member DAM may be in contact with each other to seal the organic encapsulation layer 142.

Meanwhile, the second inorganic encapsulation layer 143 may be disposed to cover the entire first inorganic encapsulation layer 141 in at least a portion of the non-display area NA. The second inorganic encapsulation layer 143 may cover the edge of the first inorganic encapsulation layer 141, thereby minimizing lifting of the first inorganic encapsulation layer 141.

Organic insulating layers made of organic materials, such as the bank 117 and the planarization layer 116, are relatively vulnerable to moisture penetration compared to inorganic insulating layers. Therefore, the edges of the bank 117 and the planarization layer 116 may be disposed in an area covered by the encapsulation layer 140. For example, the edges of the bank 117 and the planarization layer 116 may be disposed in the area covered by the encapsulation layer 140 and may be disposed on the low-potential power line VSSL.

At least some of the plurality of insulating layers of the touch unit 150 may be disposed to extend from the display area AA to the non-display area NA. For example, the touch buffer layer 151, the touch insulation layer 152, or the like may extend to the outside of the encapsulation layer 140 and cover the edge of the encapsulation layer 140. For example, the touch passivation layer 153 may extend from the display area AA to the area inside the dam member DAM. For example, the touch protection layer 154 may extend from the display area AA to the area outside the dam member DAM. However, the touch protection layer 154 may be disposed only in the area overlapping the organic encapsulation layer 142, but is not limited thereto.

Moreover, a touch display area TAA where the touch electrode TE is disposed may be disposed from the display area AA to a part of the non-display area NA. In the touch display area TAA, the touch electrode TE and the bridge electrode BE are disposed to sense a touch input. The touch display area TAA may be formed to be larger than the display area AA.

A ground line GND and a pseudo line PS may be further disposed outside the touch display area TAA within the non-display area NA, that is, in an area where the touch input is not sensed. The ground line GND and the pseudo line PS may reduce noise such as electromagnetic interference and improve touch performance, and a more detailed description thereof will be provided later.

A plurality of crack suppression patterns CSP is disposed in the non-display area NA. When manufacturing the display device 100, a configuration of the display device 100 is formed on a mother substrate, and the mother substrate may be cut into a plurality of pieces to manufacture the plurality of display devices 100. However, when cutting the mother substrate, cracks may occur in the substrate 110 or the configuration on the substrate 110 at the edge portion of the substrate 110 due to impact. The plurality of crack suppression patterns CSP are disposed along the edge of the substrate 110 and may suppress propagation of cracks into the display device 100. The plurality of crack suppression patterns CSP may be formed by patterning some of a plurality of insulating layers on the substrate 110. For example, the plurality of crack suppression patterns CSP may be formed of a multi-layer structure of an organic insulating layer and an inorganic insulating layer, but are not limited thereto.

The dam member DAM is disposed outside the organic encapsulation layer 142 in the non-display area NA. The dam member DAM is configured to suppress the overflow of the organic encapsulation layer 142 of the encapsulation layer 140. The dam member DAM may be disposed to enclose the display area AA. The dam member DAM may be disposed to enclose the organic encapsulation layer 142 of the encapsulation layer 140. The dam member DAM may be formed in a closed loop shape enclosing the display area AA and the organic encapsulation layer 142. The dam member DAM may be disposed on the low-potential power line VSSL while enclosing the organic encapsulation layer 142.

The dam member DAM may include a first dam member DAM1 and a second dam member DAM2. The first dam member DAM1 may be disposed between the second dam member DAM2 and the organic encapsulation layer 142. The first dam member DAM1 and the second dam member DAM2 may be formed from various insulating layers among the plurality of insulating layers on the substrate 110.

For example, referring to FIG. 6A, the first dam member DAM1 may be formed of a planarization layer pattern 116a made of the same material as the planarization layer 116 and a spacer pattern 130a made of the same material as the spacer 130. The second dam member DAM2 may be formed of the planarization layer pattern 116a, a bank pattern 117a made of the same material as the bank 117, and the spacer pattern 130a.

Referring to FIG. 6B, each of the first dam member DAM1 and the second dam member DAM2 may be formed of the planarization layer pattern 116a, the bank pattern 117a, and the spacer pattern 130a. The bank pattern 117a of the second dam member DAM2 may be disposed to cover a side surface of the planarization layer pattern 116a.

Referring to FIG. 6C, the first dam member DAM1 may be formed of the planarization layer pattern 116a and the spacer pattern 130a, and the second dam member DAM2 may be formed of the planarization layer pattern 116a, the bank pattern 117a, and the spacer pattern 130a. In this case, the spacer pattern 130a of the second dam member DAM2 may be formed of a plurality of slit patterns.

Therefore, the dam member DAM may be composed of a combination of various insulation layers as illustrated in FIGS. 6A to 6C.

Next, referring to FIG. 5B, a driving pad electrode PE is disposed in the non-display area NA. The driving pad electrode PE may transmit signals from the flexible film COF and the printed circuit board PCB to a link line LL and a wiring line. For example, the link line LL is disposed on an insulating layer group IL in the non-display area NA, and the driving pad electrode PE is disposed on the link line LL. The link line LL may transmit the signal from the driving pad electrode PE to the wiring line in the display area AA.

A plurality of gate conductive layers GAT may be disposed between the insulating layer groups IL in the non-display area NA. The plurality of gate conductive layers GAT may be included in various configuration, and for example, may configure the link line LL, gate driver GD, or the like.

A planarization layer dam 116P is disposed between the driving pad electrode PE and the dam member DAM in the non-display area NA. Since the planarization layer dam 116P is disposed to be spaced apart from the planarization layer 116 in the display area AA, it is possible to suppress the penetration of moisture into the display area AA through the planarization layer dam 116P. In addition, the planarization layer dam 116P may compensate for the step of the dam member DAM, thereby minimizing disconnection of the touch line TL or the like due to the step.

And referring to FIG. 2 and FIG. 7 together, the dam member DAM is configured in a closed loop shape enclosing the display area AA, so that at least some of the wiring lines extending from the pad unit PAD to the display area AA may intersect the dam member DAM. In particular, after the dam member DAM is formed, the encapsulation layer 140 and the touch unit 150 may be formed. Moreover, the wiring lines of the touch unit 150, for example, the link line LL functioning as the touch line TL, the pseudo line PS, and the ground line GND, may pass through the dam member DAM. In this case, the link line LL passing through the dam member DAM may be easily disconnected due to the step of the dam member DAM. Therefore, the width of a portion of the link line LL overlapping the dam member DAM may be formed wide to suppress the disconnection of the link line LL over the dam member DAM. As shown in FIG. 7, the portion of the link line LL overlapping the dam member DAM has a width greater than a width of another portion of the link line LL spaced apart from the dam member DAM.

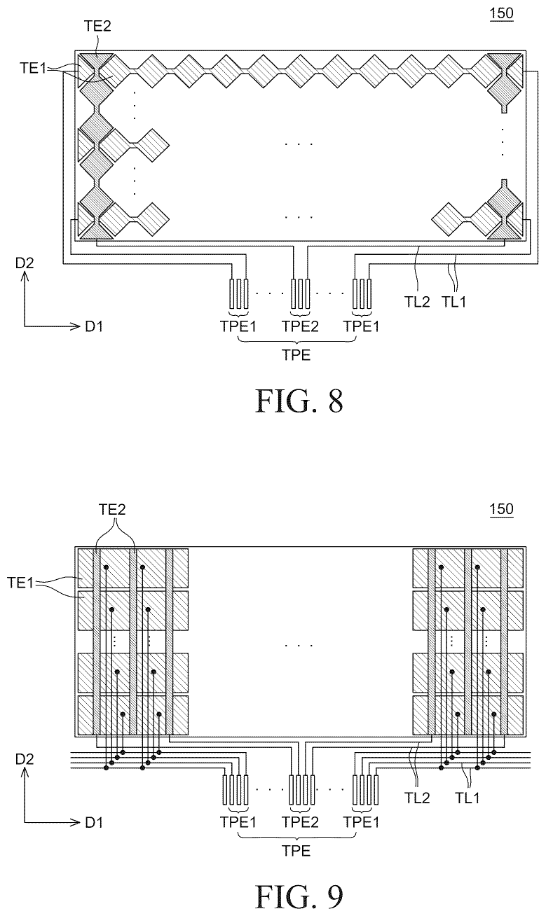

Hereinafter, the touch unit 150 of the display device 100 according to an example embodiment of the present disclosure will be described in more detail with reference to FIGS. 8 to 23B.

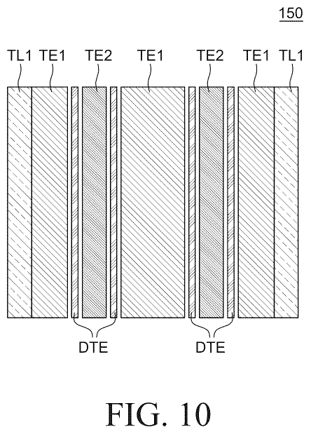

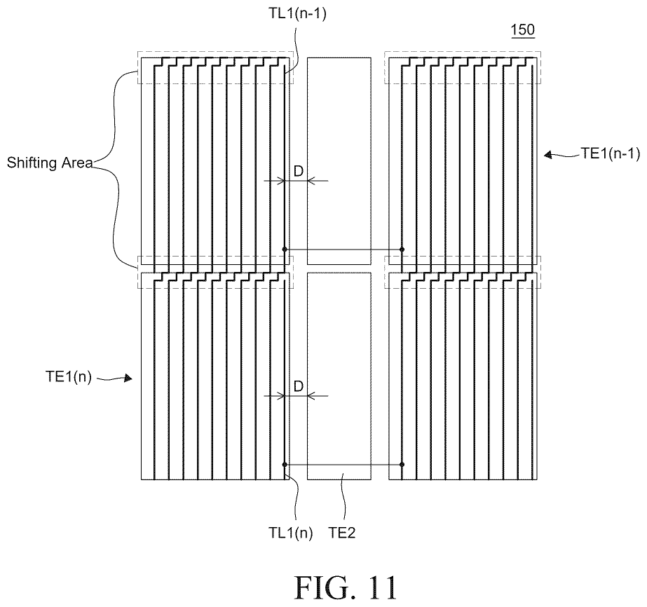

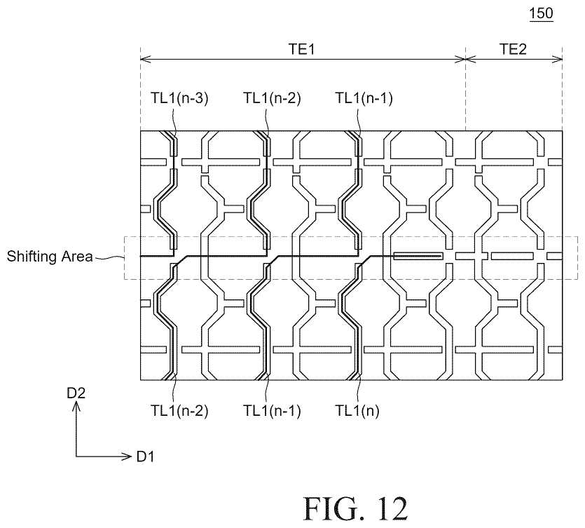

FIGS. 8 and 9 are schematic plan views of the touch unit of the display device according to an example embodiment of the present disclosure. FIG. 10 is a schematic enlarged plan view of the touch unit of the display device according to an example embodiment of the present disclosure. FIGS. 11 and 12 are schematic enlarged plan views of the touch unit of the display device according to an example embodiment of the present disclosure.

First, the touch unit 150 may sense touch input using a mutual-capacitance method or a self-capacitance method. The mutual-capacitance method is a method of sensing touch input based on a change in capacitance between a touch driving electrode and a touch sensing electrode. The self-capacitance method is a method of sensing touch input based on a change in capacitance between an external input and a touch electrode.

Hereinafter, it will be explained assuming that the touch unit 150 of the display device 100 according to an example embodiment of the present disclosure is the touch unit 150 that uses the mutual-capacitance method and the self-capacitance method in combination.

Referring to FIGS. 8 and 9, the touch unit 150 includes a plurality of touch lines TL and a plurality of touch electrodes TE. The plurality of touch lines TL includes a plurality of first touch lines TL1 and a plurality of second touch lines TL2, and the plurality of touch electrodes TE includes a plurality of first touch electrodes TE1 and a plurality of second touch electrodes TE2. In this case, as illustrated in FIGS. 8 and 9, the shape and disposition of the plurality of touch electrodes TE of the touch unit 150 and the connection structure of the touch electrodes TE and the touch lines TL may be configured in various ways.

For example, referring to FIG. 8, the plurality of first touch electrodes TE1 may be disposed in a matrix form with a predetermined interval. Each of the plurality of first touch electrodes TE1 may be formed in a diamond shape. In addition, among the plurality of first touch electrodes TE1, the first touch electrodes TE1 of the same line disposed along the first direction D1 may be connected to each other. For example, the first touch electrodes TE1 of the nth row may be electrically connected to each other to form a line of one first touch electrode TE1.

The plurality of second touch electrodes TE2 may be disposed in a matrix form with a predetermined interval. Each of the plurality of second touch electrodes TE2 may be formed in a diamond shape. The plurality of second touch electrodes TE2 may be disposed to be staggered with the plurality of first touch electrodes TE1. Among the plurality of second touch electrodes TE2, the second touch electrodes TE2 in the same line disposed along the second direction D2 may be connected. For example, the second touch electrodes TE2 in the nth column may be electrically connected to each other to form a line of one second touch electrode TE2. Accordingly, the line of the first touch electrode TE1 and the line of the second touch electrode TE2 may intersect each other.

The plurality of first touch lines TL1 are electrically connected to the plurality of first touch electrodes TE1. The plurality of first touch lines TL1 is electrically connected to a first touch pad electrode TPE1 among the plurality of touch pad electrodes TPE, and may transmit the touch signal from the first touch pad electrode TPE1 to the plurality of first touch electrodes TE1. For example, the first touch lines TL1 may be connected to both ends of a line of one first touch electrode TE1 composed of the plurality of first touch electrodes TE1 disposed in the same row. By supplying a touch signal to both ends of the line of the first touch electrode TE1, a signal delay can be minimized.

The plurality of second touch lines TL2 is electrically connected to the plurality of second touch electrodes TE2. The plurality of second touch lines TL2 is electrically connected to a second touch pad electrode TPE2 among the plurality of touch pad electrodes TPE, and the second touch pad electrode TPE2 and the plurality of second touch electrodes TE2 can be electrically connected to each other. For example, the second touch line TL2 may be connected to one end of a line of the second touch electrode TE2 composed of the plurality of second touch electrodes TE2 disposed in the same column.

The touch unit 150 of FIG. 8 may be configured with a dual-feeding structure that simultaneously applies signals to both ends of the line of the touch electrodes TE. For example, as the size of the display device 100 increases, the length of the line of touch electrodes TE formed by the same line of touch electrodes TE increases, and signal transmission may be delayed depending on the position of the touch electrodes TE. Accordingly, in order to reduce the time deviation of transmitting and receiving a touch signal, two or more touch lines TL may be connected to the same line constituting the line of touch electrodes TE to minimize the signal delay.

Next, referring to FIG. 9, the plurality of first touch electrodes TE1 may be disposed in a matrix form with a predetermined interval. Each of the plurality of first touch electrodes TE1 may have a rectangular shape. Among the plurality of first touch electrodes TE1, the first touch electrodes TE1 of the same line disposed along the first direction D1 may receive a signal at the same time. For example, a plurality of first touch pad electrodes TPE1 is disposed in the non-display area NA, and an nth first touch line TL1 electrically connected to an nth first touch pad electrode TPE1 of the plurality of first touch pad electrodes TPE1 may be connected to the plurality of first touch electrodes TE1 disposed in the same line.

The plurality of second touch electrodes TE2 may be disposed between the plurality of first touch electrodes TE1. Each of the plurality of second touch electrodes TE2 may have a rectangular shape. For example, the plurality of first touch electrodes TE1 and the plurality of second touch electrodes TE2 may be disposed alternately in the first direction D1. The first touch electrodes TE1 and the second touch electrodes TE2 may be disposed in the same row, and the first touch electrodes TE1 and the second touch electrodes TE2 may be disposed in different columns. Among the plurality of second touch electrodes TE2, the second touch electrodes TE2 in the same line disposed along the second direction D2 may receive a signal at the same time. For example, the plurality of second touch pad electrodes TPE2 are disposed in the non-display area NA, and an nth second touch line TL2 electrically connected to an nth second touch pad electrode TPE2 among the plurality of second touch pad electrodes TPE2 may be connected to the plurality of second touch electrodes TE2 disposed in the same line.

The plurality of first touch lines TL1 is electrically connected to the plurality of first touch electrodes TE1. The plurality of first touch lines TL1 is electrically connected to the first touch pad electrode TPE1 among the plurality of touch pad electrodes TPE, and may transmit the touch signal from the first touch pad electrode TPE1 to the plurality of first touch electrodes TE1.

The plurality of second touch lines TL2 is electrically connected to the plurality of second touch electrodes TE2. The plurality of second touch lines TL2 may be electrically connected to the second touch pad electrode TPE2 among the plurality of touch pad electrodes TPE, and the second touch pad electrode TPE2 and the plurality of second touch electrodes TE2 may be electrically connected to each other.

Meanwhile, the touch unit 150 of FIG. 9 may be configured with a multi-feeding structure that simultaneously applies signals to the plurality of touch electrodes TE. For example, as the size of the display device 100 increases, the length of the line of touch electrodes TE formed by the touch electrodes TE of the same line may increase, and signal transmission may be delayed depending on the position of the touch electrodes TE. Accordingly, in order to reduce the time deviation of transmitting and receiving the touch signals, the touch line TL may be connected to each of the plurality of touch electrodes TE of the same line that constitutes the line of touch electrodes TE so that signals may be simultaneously applied. Accordingly, by connecting the plurality of touch lines TL one-to-one to each of the plurality of touch electrodes TE, the delay of the touch signal may be reduced, and the touch performance for the entire area of the display device 100 may be improved.

Moreover, the plurality of first touch electrodes TE1 may be touch driving electrodes, and the plurality of second touch electrodes TE2 may be touch sensing electrodes. Furthermore, the plurality of first touch lines TL1 may be touch driving lines, and the plurality of second touch lines TL2 may be touch sensing lines. In this case, the touch driver TD may transmit the touch driving signal to the first touch electrode TE1 through the first touch line TL1, and receive the touch sensing signal from the second touch electrode TE2 through the second touch line TL2.

However, the first touch electrode TE1 and the first touch line TL1 may each be the touch sensing electrode and the touch sensing line, and the second touch electrode TE2 and the second touch line TL2 may each be a touch driving electrode and a touch driving line, and the embodiments of the present disclosure are not limited thereto.

Referring to FIG. 10, the plurality of touch electrodes TE may further include a plurality of dummy touch electrodes DTE. The dummy touch electrodes DTE may be disposed between the plurality of first touch electrodes TE1 and the plurality of second touch electrodes TE2. For example, the dummy touch electrode DTE may be disposed between the first touch electrode TE1 and the second touch electrode TE2 adjacent to each other. For example, the plurality of touch electrodes TE and the plurality of dummy touch electrodes DTE may be disposed at equal intervals. By disposing the dummy touch electrodes DTE, the distance between the first touch electrodes TE1 and the second touch electrodes TE2 may be secured, and the initial capacitance value between the first touch electrodes TE1 and the second touch electrodes TE2 may be reduced.

The touch input may be sensed by sensing the capacitance between the first touch electrode TE1 and the second touch electrode TE2. In this case, as the first touch electrode TE1 and the second touch electrode TE2 get closer, the initial capacitance value between the first touch electrode TE1 and the second touch electrode TE2 may increase, making it somewhat difficult to sense the capacitance change.

For example, when the first touch electrode TE1 and the second touch electrode TE2 are disposed at a first interval without the dummy touch electrode DTE, it can be assumed that the initial capacitance value between the first touch electrode TE1 and the second touch electrode TE2 is 100, and the amount of capacitance change during touch input is 10. In this case, the difference between the initial capacitance value of 100 and the capacitance value during touch input of 110 is small, so it may be somewhat difficult to detect the touch.

Moreover, when the dummy touch electrode DTE is formed between the first touch electrode TE1 and the second touch electrode TE2, the gap between the first touch electrode TE1 and the second touch electrode TE2 increases. Accordingly, the initial capacitance value between the first touch electrode TE1 and the second touch electrode TE2 may decrease. For example, when the dummy touch electrode DTE is disposed between the first touch electrode TE1 and the second touch electrode TE2, the gap between the first touch electrode TE1 and the second touch electrode TE2 may increase by the gap and the width of the dummy touch electrode DTE. Accordingly, the initial capacitance value may decrease to a value less than 100, for example, 50. In this case, when the amount of capacitance change during touch input is 10, the difference between the initial capacitance value of 50 and the capacitance value during touch input of 60 is relatively large, so that the touch can be easily detected.

Accordingly, by placing the dummy touch electrode DTE between the first touch electrode TE1 and the second touch electrode TE2, the gap between the first touch electrode TE1 and the second touch electrode TE2 may be secured, and the initial capacitance value between the first touch electrode TE1 and the second touch electrode TE2 may be lowered. Therefore, it is possible to improve the performance of the touch unit 150.

Next, referring to FIGS. 9 and 11, in the touch unit 150 of the multi-feeding structure, the plurality of first touch lines TL1 is disposed around the plurality of second touch electrodes TE2, and parasitic capacitance may be formed between the plurality of first touch lines TL1 and the second touch electrodes TE2. However, when the parasitic capacitance variation occurs between the plurality of first touch lines TL1 and the second touch electrodes TE2, the touch performance may be degraded. Therefore, in the display device 100 according to an example embodiment of the present disclosure, a gap D between the second touch electrodes TE2 and the first touch lines TL1 may be uniformly formed, thereby minimizing the parasitic capacitance variation.

Specifically, the plurality of first touch lines TL1 may extend in the second direction D2 and be electrically connected to the plurality of first touch electrodes TE1 through contact holes. In this case, by shifting the first touch lines TL1 by one line in the first direction D1, a distance D between the contact holes through which the first touch electrodes TE1 and the first touch lines TL1 are connected and the second touch electrodes TE2 may be configured to be constant.

First, an area between the plurality of first touch electrodes TE1 in the second direction D2, for example, an area between the first touch electrode TE1(n) of the nth row and the first touch electrode TE1(n−1) of the n−1th row and an area between the first touch electrode TE1(n) of the nth row and the first touch electrode TE1(n+1) of the n+1th row may be defined as a shifting area in which the first touch line TL1 shifts.

In the nth row, the nth first touch line TL1(n) may be disposed closest to the second touch electrode TE2. In the nth row, the contact hole through which the nth first touch line TL1(n) and the first touch electrode TE1(n) are connected and the second touch electrode TE2 may be disposed to be spaced apart from each other with the gap (e.g. distance) D.

In addition, the contact hole of the first touch electrode TE1(n) and the first touch line TL1(n) located on the right side of the second touch electrode TE2 and the contact hole of the first touch electrode TE1(n) and the first touch line TL1(n) located on the left side of the second touch electrode TE2 may be disposed symmetrically with respect to the second touch electrode TE2, but the present disclosure is not limited thereto. For example, the contact hole of the first touch electrode TE1(n) and the first touch line TL1(n) located on the right side of the second touch electrode TE2 and the contact hole of the first touch electrode TE1(n) and the first touch line TL1(n) located on the left side of the second touch electrode TE2 may be disposed in the same manner, as shown in FIG. 11.

Moreover, the first touch line TL1(n) of the nth row for transmitting a signal to the first touch electrode TE1(n) of the nth row is electrically connected to the nth first touch electrode TE1(n). Accordingly, the first touch line TL1(n) is located only up to the shifting area between the nth first touch electrode TE1(n) and the n−1th first touch electrode TE1(n−1), and does not extend to the area of the n−1th first touch electrode TE1(n−1).

Moreover, first, the first touch line TL1 to the (n−1)th first touch line TL1(n−1) may be shifted in the first direction D1 in the shifting area and extended again onto the (n−1)th first touch electrode TE1(n−1). In the (n−1)th row, the (n−1)th first touch line TL1(n−1) may be electrically connected to the first touch electrode TE1(n−1). Moreover, in the (n−1)th row, the contact hole through which the (n−1)th first touch line TL1(n−1) and the first touch electrode TE1(n−1) are connected and the second touch electrode TE2 may be disposed spaced apart from each other by the gap D.

Accordingly, by shifting the remaining first touch lines TL1 except for the nth first touch line TL1(n) connected to the nth first touch electrode TE1(n) in the shifting area and extending them in the second direction D2, the gap D between the contact hole connecting the first touch electrode TE1 and the first touch line TL1 and the second touch electrode TE2 may be configured to be the same.

Meanwhile, the plurality of touch electrodes TE may have a plate-shaped structure as illustrated in FIG. 11, but the plurality of touch electrodes TE may also be formed in a mesh structure as illustrated in FIG. 12. Even when the plurality of touch electrodes TE is formed in a mesh structure as illustrated in FIG. 12, a shifting area may be formed.

Referring to FIG. 12, the plurality of touch electrodes TE may be formed in a mesh structure, and openings of the mesh structure may overlap each of the plurality of sub-pixels SP. The metal of the plurality of touch electrodes TE may be disposed in an area between the plurality of sub-pixels SP. For example, the metal of the plurality of touch electrodes TE may be disposed in an octagonal shape in an area between the sub-pixels SP.

The first touch line TL1 may extend in a second direction D2 along the metal forming the first touch electrode TE1. The first touch line TL1 may be electrically connected to the metal of the first touch electrode TE1 through a contact hole in an area spaced away from the second touch electrode TE2 by a distance. In addition, the plurality of first touch lines TL1 may be shifted in the first direction D1 in a shifting area and then extend upward again.

Accordingly, the shifting area can be formed in the touch unit 150 of various structures, thereby forming a constant distance between the contact hole where the first touch electrode TE1 and the first touch line TL1 are connected and the second touch electrode TE2.

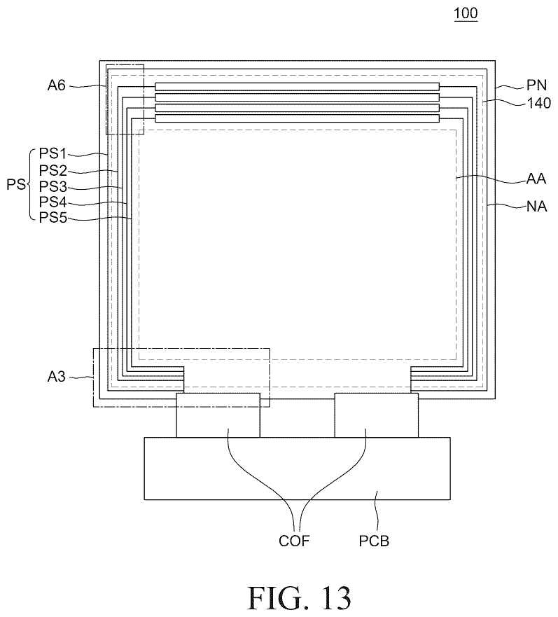

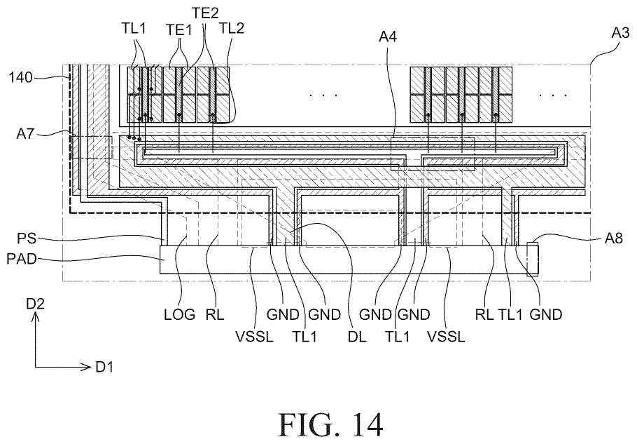

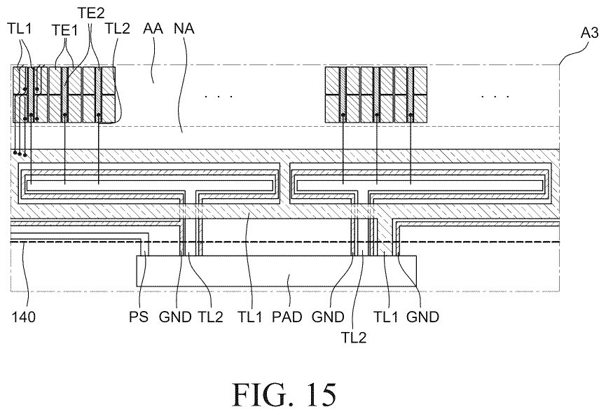

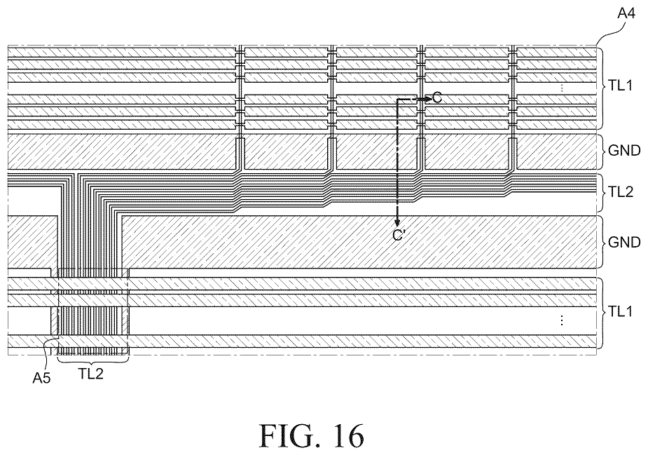

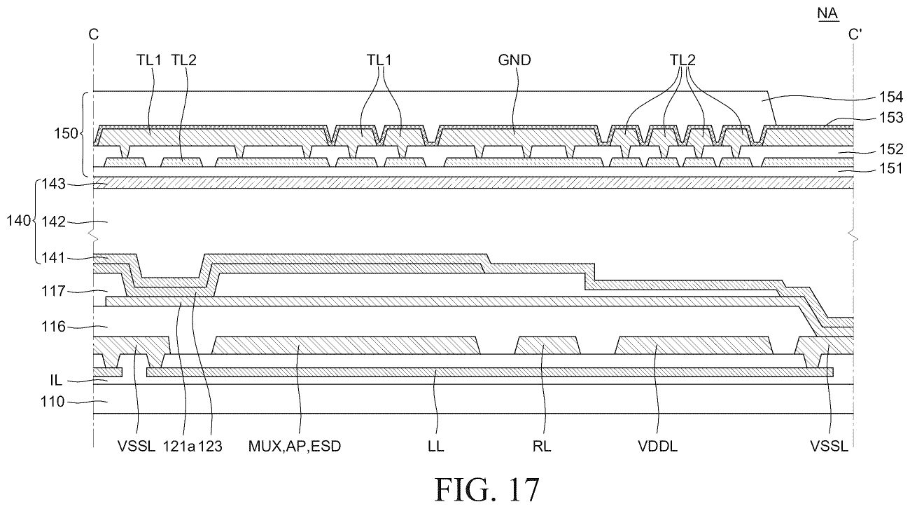

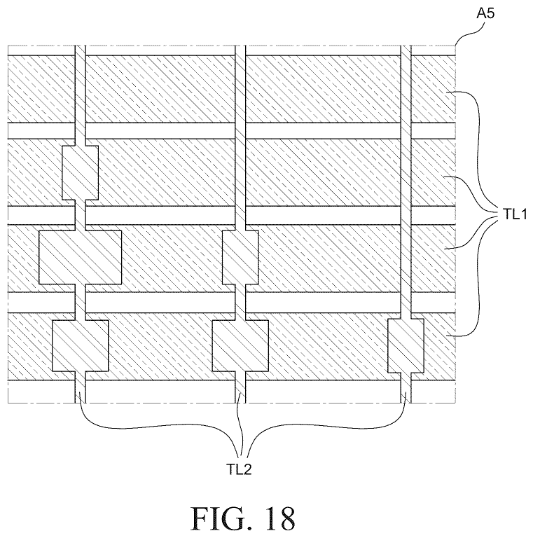

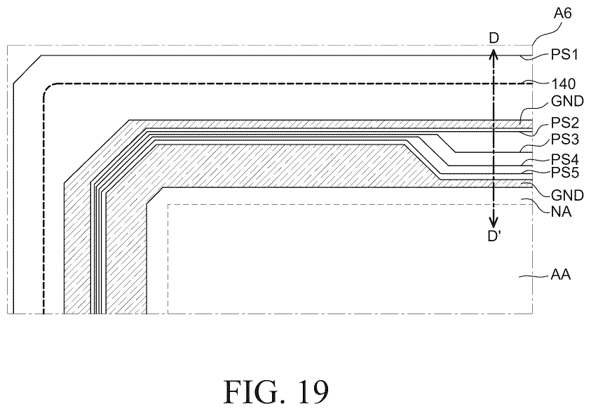

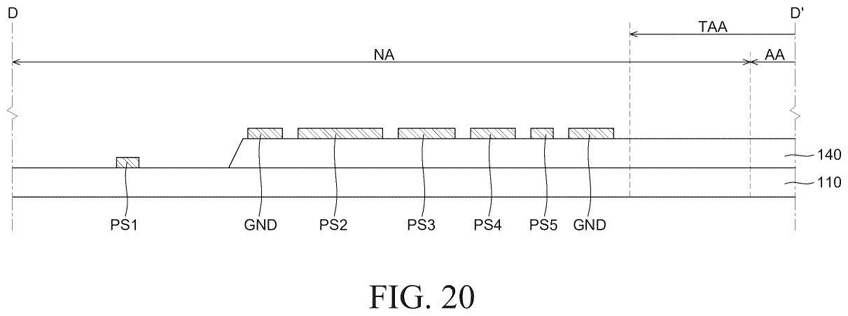

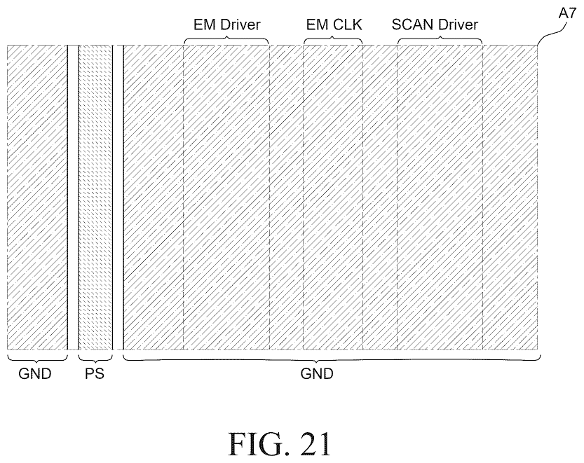

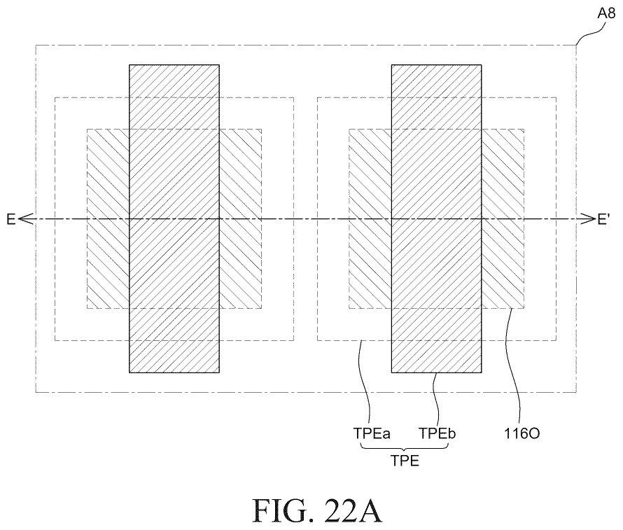

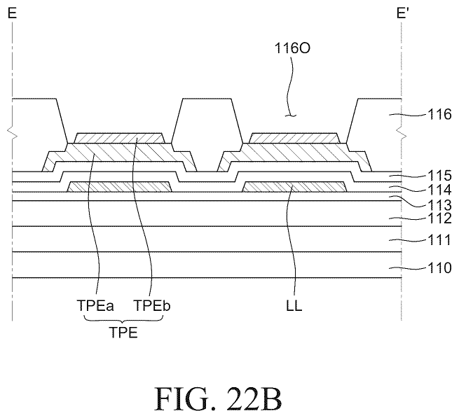

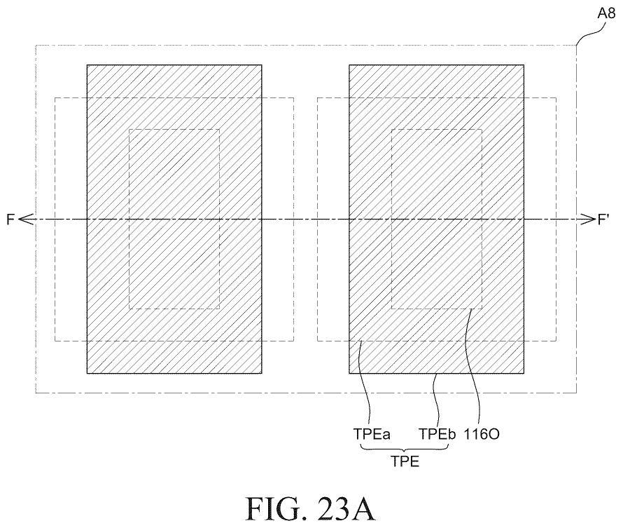

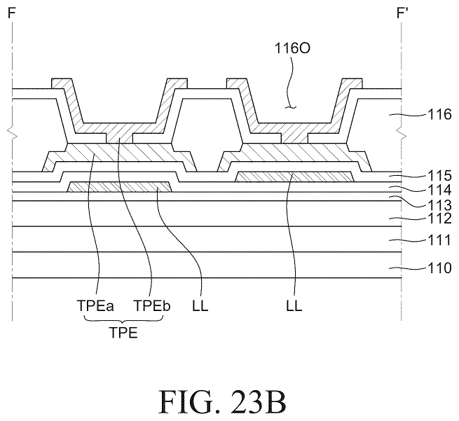

FIG. 13 is a schematic plan view of a display device according to an example embodiment of the present disclosure. FIGS. 14 and 15 are enlarged plan views of an area A3 of FIG. 13. FIG. 16 is an enlarged plan view of an area A4 of FIG. 14. FIG. 17 is a cross-sectional view taken along line C-C′ of FIG. 16. FIG. 18 is an enlarged plan view of an area A5 of FIG. 16. FIG. 19 is an enlarged plan view of an area A6 of FIG. 13. FIG. 20 is a cross-sectional view taken along line D-D′ of FIG. 19. FIG. 21 is an enlarged plan view of an area A7 of FIG. 14. FIG. 22A is an enlarged plan view of an area A8 of FIG. 14. FIG. 22B is a cross-sectional view taken along line E-E′ of FIG. 22A. FIG. 23A is an enlarged plan view of an area A8 of FIG. 14. FIG. 23B is a cross-sectional view taken along line F-F′ of FIG. 23A. For convenience of explanation, in FIG. 14, among the plurality of wiring lines, the touch line TL, ground line GND, and pseudo line PS are drawn as solid lines, and the reference line RL, LOG line LOG, data line DL, and low-potential power line VSSL are drawn as dotted lines.

Referring to FIGS. 13 and 14 together, wiring lines related to the touch unit 150 are disposed in the non-display area NA. For example, the pseudo line PS, the plurality of touch lines TL, and the plurality of ground lines GND may be disposed in the non-display area NA.

Meanwhile, the display device 100 according to an example embodiment of the present disclosure has a Touch On Encap (TOE) structure in which the touch unit 150 is disposed on the encapsulation layer 140, and most of the wiring lines related to the touch unit 150 may extend onto the encapsulation layer 140. Accordingly, the wiring lines related to driving the display device 100 illustrated in FIG. 4 and the wiring lines related to the touch unit 150 illustrated in FIG. 14 can be disposed on different layers, and at least some of the wiring lines may be disposed spaced apart from each other with the encapsulation layer 140 interposed therebetween.

For convenience of explanation, the wiring line related to driving the display device 100 and the wiring line related to the touch unit 150 among the wiring lines in the non-display area NA are each drawn as solid lines in FIGS. 4 and 14, but the wiring lines in the non-display area NA illustrated in FIGS. 4 and 14 are actually overlapping each other.

In addition, for convenience of explanation, each wiring line is represented as a single wiring line in FIGS. 4 and 14, but each wiring line may be composed of at least one group of wiring lines. For example, in FIG. 14, each of the touch lines TL and the pseudo lines PS is depicted as a single wiring line, but the touch lines TL and the pseudo lines PS may be composed of a group of a plurality of touch lines TL and a group of a plurality of pseudo lines PS.

Referring to FIG. 14, the plurality of first touch lines TL1 includes a portion extending in the second direction D2 from the touch pad electrode TPE of the pad unit PAD and another portion extending in the first direction D1 from the portion and disposed in a closed loop shape. For example, in the non-display area NA, the plurality of first touch lines TL1 may be formed of a first vertical line portion extending from the pad unit PAD toward the encapsulation layer 140 and a first horizontal line portion having a loop shape and having an empty space therein, which is disposed on the encapsulation layer 140. In addition, the plurality of first touch lines TL1 may branch from the first horizontal line portions of the plurality of first touch lines TL1 in the second direction D2 and may be connected to the plurality of first touch electrodes TE1 in the display area AA.

In this case, at least one region in which the first vertical line portions of the plurality of first touch lines TL1 are connected to the pad unit PAD may be disposed in the non-display area NA. For example, in FIG. 14, the first vertical line portions of the plurality of first touch lines TL1 are connected to two regions of the pad unit PAD, and in FIG. 15, the first vertical line portions of the plurality of first touch lines TL1 may be connected to one region of the pad unit PAD.

Additionally, the first horizontal line portions of the plurality of first touch lines TL1 in the non-display area NA may form at least one loop. For example, in FIG. 14, the first horizontal line portions of the plurality of first touch lines TL1 may form one loop, and in FIG. 15, the first horizontal line portions of the plurality of first touch lines TL1 may form two loops.

The plurality of second touch lines TL2 include a portion extending in the second direction D2 from the touch pad electrode TPE of the pad unit PAD, and another portion extending in the first direction D1 from the portion and disposed in a bar shape. For example, in the non-display area NA, the plurality of second touch lines TL2 may be formed of a second vertical line portion extending from the pad unit PAD toward the encapsulation layer 140 and a second horizontal line portion disposed on the encapsulation layer 140 in a bar shape. The second horizontal line portions of the plurality of second touch lines TL2 may be disposed in an empty space inside the first horizontal line portions of the plurality of first touch lines TL1. That is, the first horizontal line portions of the plurality of first touch lines TL1 in a loop shape may be disposed to enclose the second horizontal line portions of the plurality of second touch lines TL2. Moreover, the plurality of second touch lines TL2 may be branched from the second horizontal line portion of the plurality of second touch lines TL2 in the second direction D2 and connected to the plurality of second touch electrodes TE2 in the display area AA.

Meanwhile, at least a portion of the plurality of touch lines TL in the non-display area NA may be disposed outside the encapsulation layer 140. In this case, in the area where the encapsulation layer 140 is not disposed, the touch lines TL and the data lines DL are disposed relatively close together, and thus their signals may interfere with each other. Accordingly, a constant voltage line capable of shielding signals may be disposed at the intersection of the data lines DL and the touch lines TL in the area outside the encapsulation layer 140 to minimize signal interference.

For example, the low-potential power lines VSSL may be disposed between the plurality of first touch lines TL1 and the plurality of data lines DL in an area outside the encapsulation layer 140, and between the plurality of second touch lines TL2 and the plurality of data lines DL, thereby minimizing signal interference between the touch signal and the data voltage Vdata and improving touch sensing performance.

For example, the second horizontal line portions of the plurality of second touch lines TL2 extending in the first direction D1 in the non-display area NA may be disposed to overlap the shorting-bar-shaped reference line RL. Accordingly, the shorting-bar-shaped reference line RL may be disposed between the plurality of data lines DL and the second horizontal line portions of the plurality of second touch lines TL2, thereby functioning as a protective film that minimizes signal interference between the plurality of data lines DL and the second touch lines TL2.

Next, referring to FIG. 14, the plurality of pseudo lines PS is disposed in the non-display area NA. The plurality of pseudo lines PS may be disposed to enclose the display area AA. When the display device 100 transmits and receives a wireless signal with another device, electromagnetic interference with the touch signal may occur, and the transmission and reception performance of the wireless signal and the touch sensing performance may deteriorate. The plurality of pseudo lines PS is wiring lines for canceling the electromagnetic interference between the wireless signal and the touch signal, and the electromagnetic interference may be canceled by supplying a pseudo touch signal of an opposite phase to the touch driving signal to the plurality of pseudo lines PS.

Referring to FIG. 14, the plurality of ground lines GND is disposed between the plurality of touch lines TL and the plurality of pseudo lines PS. By discharging noise charges or the like flowing into the display panel PN to the ground voltage of the ground lines GND, the touch lines TL and pseudo lines PS may be protected, and touch sensing performance may be improved.

Some of the plurality of ground lines GND may extend along the plurality of touch lines TL and may be disposed adjacent to each of the plurality of touch lines TL. For example, some of the plurality of ground lines GND may be disposed along first vertical line portions and first horizontal line portions of the plurality of first touch lines TL1, and other some of the plurality of ground lines GND may be disposed along second vertical line portions and second horizontal line portions of the plurality of second touch lines TL2. For example, another some of the plurality of ground lines GND may be disposed between first horizontal line portions of the plurality of first touch lines TL1 in a loop shape and second horizontal line portions of the plurality of second touch lines TL2 and may be formed in a loop shape. For example, other some of the plurality of ground lines GND may extend along the plurality of pseudo lines PS and may be disposed adjacent to each of the plurality of pseudo lines PS.

Moreover, referring to FIGS. 13, 14, 19 and 20 together, some of the plurality of pseudo lines PS and the plurality of ground lines GND in the non-display area NA may be disposed on the encapsulation layer 140, and the remainder may be disposed in an area outside the encapsulation layer 140. For example, the plurality of pseudo lines PS may include a first pseudo line PS1, a second pseudo line PS2, a third pseudo line PS3, a fourth pseudo line PS4, and a fifth pseudo line PS5. Among the plurality of pseudo lines PS, the first pseudo line PS1 may be disposed in an area outside the encapsulation layer 140, and the second pseudo line PS2, the third pseudo line PS3, the fourth pseudo line PS4, and the fifth pseudo line PS5 may be disposed on the encapsulation layer 140.

The ground line GND may be disposed on both sides of the second pseudo line PS2, the third pseudo line PS3, the fourth pseudo line PS4, and the fifth pseudo line PS5 on the encapsulation layer 140, as shown in FIGS. 19 and 20. The ground line GND between the first pseudo line PS1 and the second pseudo line PS2 may alleviate electromagnetic interference between configurations disposed below a plurality of pseudo lines PS, for example, the gate driver GD (refer to FIG. 5A) and the plurality of pseudo lines PS. The ground line GND between the fifth pseudo line PS5 and the display area AA may function as a protective film that inhibits the configurations of the display area AA and the pseudo lines PS from being influenced by each other, thereby alleviating electromagnetic interference.

Moreover, one or more pseudo lines PS may be disposed in an area outside the encapsulation layer 140, and a ground line GND may be further disposed outside the pseudo line PS. For example, referring to FIG. 5A, one or more pseudo lines PS may be disposed in an area outside the encapsulation layer 140, and the ground line GND may be disposed in an area outside the pseudo line PS. Moreover, the ground line GND disposed at the outermost side may discharge static electricity to protect other components inside the display device 100, including the pseudo line PS.

Meanwhile, in FIG. 13, FIG. 19, and FIG. 20, it is illustrated that there are five pseudo lines PS and only the first pseudo line PS1 is disposed outside the encapsulation layer 140. However, the disposition and number of the pseudo lines PS may be changed in consideration of the size of the non-display area NA, the formation area of the encapsulation layer 140, or the like, and the embodiments of the present disclosure are not limited thereto.

Next, referring to FIG. 16, in region of the non-display area NA above the second horizontal line portions of the plurality of second touch lines TL2, the widths of the plurality of first touch lines TL1 may be narrowed at points where the plurality of first touch lines TL1 and the plurality of second touch lines TL2 intersect. The width of a portion of the plurality of first touch lines TL1 that intersects the plurality of second touch lines TL2 may be narrower than the width of another portion that does not intersect the plurality of second touch lines TL2. By configuring the widths of the plurality of first touch lines TL1 to be narrow at points where the plurality of first touch lines TL1 and the plurality of second touch lines TL2 intersect, interference between the plurality of first touch lines TL1 and the plurality of second touch lines TL2 can be minimized.

Referring to FIGS. 16 and 17 together, the first touch line TL1, the second touch line TL2, and the ground line GND may be formed as a double wiring line structure. For example, each of the first touch line TL1, the second touch line TL2, and the ground line GND may be formed as a bilayer structure of the bridge metal BM on the touch buffer layer 151 and the sensor metal SM on the touch insulation layer 152. In addition, the bridge metal BM and the sensor metal SM of each of the first touch line TL1, the second touch line TL2, and the ground line GND may be connected to each other through the contact hole of the touch insulation layer 152.

In this case, at the intersection of the first touch line TL1 and the second touch line TL2, the first touch line TL1 and the second touch line TL2 may use different metals. For example, at the intersection of the first touch line TL1 and the second touch line TL2, the first touch line TL1 may be composed only of a sensor metal SM on the touch insulation layer 152, and the second touch line TL2 may be composed only of a bridge metal BM between the touch buffer layer 151 and the touch insulation layer 152.

Meanwhile, the cathode 123 may be electrically connected to the low-potential power line VSSL using an anode pattern 121a in the non-display area NA. For example, the anode pattern 121a of the same material as the anode 121 may be connected to the low-potential power line VSSL in the non-display area NA. In addition, an opening in which the anode pattern 121a is exposed may be formed in the bank 117, and the cathode 123 may be extended from the display area AA to the opening. Therefore, the cathode 123, the anode pattern 121a, and the low-potential power line VSSL may be electrically connected to each other.

In addition, in the non-display area NA, the multiplexer circuit MUX, the light inspection transistor AP, the electrostatic discharge protection circuit ESD, and the like are disposed below the touch unit 150. Moreover, the shorting-bar-shaped reference line RL, the high-potential power line VDDL, and the low-potential power line VSSL, or the like described in FIG. 4 may also be disposed.

Next, referring to FIG. 18, in a region of the non-display area NA below the second horizontal line portions of the plurality of second touch lines TL2, the width of the plurality of second touch lines TL2 may be varied at a point where the plurality of first touch lines TL1 and the plurality of second touch lines TL2 intersect, thereby compensating for the capacitance variation of each of the plurality of touch lines TL.

For example, each of the plurality of touch lines TL may have a different length depending on the shape of the display device 100, the position of the touch electrode TE, or the like. For example, when the display device 100 has a non-rectangular shape, the lengths of the plurality of touch lines TL may vary by region. When the lengths of the plurality of touch lines TL are different, the capacitance variation may occur depending on the difference in the overlapping size between the plurality of touch lines TL. For example, when the lengths of the plurality of second touch lines TL2 are different, the overlapping size between each of the plurality of second touch lines TL2 and the first touch line TL1 is different, and the capacitance value between each of the plurality of second touch lines TL2 and the first touch line TL1 may also vary. Accordingly, by varying the width of the second touch line TL2, the overlapping size between the first touch line TL1 and the second touch line TL2 and the capacitance value resulting therefrom may be controlled.

For example, when the second touch line TL2 on the left among the three second touch lines TL2 has a relatively short length, the width of the second touch line TL2 may be widened in three areas among the intersection areas of the second touch line TL2 on the left and the plurality of first touch lines TL1. Therefore, it is possible to increase the overlapping size of the first touch line TL1 and the second touch line TL2 and increase the capacitance. For example, when the second touch line TL2 on the right among the three second touch lines TL2 has a relatively long length, the width of the second touch line TL2 may be widened in only one area among the intersection areas of the second touch line TL2 and the plurality of first touch lines TL1. Therefore, by varying the width of the second touch line TL2 at the intersection points of the first touch lines TL1 and the second touch lines TL2, the capacitance variation of each of the plurality of touch lines TL can be reduced.

Meanwhile, referring to FIG. 21 and FIG. 5A together, the area where the LOG line LOG is disposed is the area where the gate driver GD is disposed, and the scan signal driver SCAN Driver or the light emission signal driver EM Driver that constitutes the gate driver GD may be disposed together. For example, in the non-display area NA, the light emission signal driver EM Driver and the scan signal driver SCAN Driver may be disposed, and the LOG line LOG, for example, an emission clock signal line EM CLK, may be disposed between the light emission signal driver EM Driver and the scan signal driver SCAN Driver.

In this case, the plurality of pseudo lines PS may be disposed in the non-display area NA and may overlap the gate driver GD (refer to FIG. 5A), and accordingly, electromagnetic interference or the like may occur between the plurality of pseudo lines PS and the gate driver GD. Accordingly, the width of the ground line GND disposed adjacent to the plurality of pseudo lines PS and overlapping the gate driver GD may be formed wider. For example, the ground line GND may be disposed to cover all of the scan signal driver SCAN Driver and the light emission signal driver EM Driver of the gate driver GD and the LOG line LOG. For example, the width of the ground line GND overlapping the gate driver GD may be wider than the width of the gate driver GD. For example, the width of a portion of the ground line GND overlapping the gate driver GD is greater than the sum of the width of the scan signal driver SCAN Driver and the width of the light emission signal driver EM Driver. The ground line GND may function as a protective film that shields the signal of the gate driver GD from affecting the plurality of pseudo lines PS. Therefore, by forming the ground line GND overlapping the gate driver GD with a wide width, which is disposed on one side of the plurality of pseudo lines PS, the electromagnetic interference between the gate driver GD and the pseudo lines PS can be minimized.

Next, referring to FIGS. 22A to 23B, the pad unit PAD may further include a plurality of touch pad electrodes TPE to which wiring lines related to the driving unit 150 are connected, in addition to a plurality of driving pad electrodes PE to which wiring lines related to driving the display panel PN are connected. The plurality of touch pad electrodes TPE may be formed in various structures.

For example, referring to FIGS. 22A and 22B, the touch pad electrode TPE is disposed on the pad unit PAD. The flexible film COF may be bonded on the touch pad electrode TPE to connect the touch driver TD and the touch unit 150. The touch pad electrode TPE includes a first pad conductive layer TPEa and a second pad conductive layer TPEb on the first pad conductive layer TPEa.

The first pad conductive layer TPEa is disposed between the second interlayer insulating layer 115 and the planarization layer 116, and the planarization layer 116 includes an opening 116O through which the first pad conductive layer TPEa is exposed. The opening 116O of the planarization layer 116 may have a smaller size than the first pad conductive layer TPEa.

The second pad conductive layer TPEb is disposed on the planarization layer 116. The second pad conductive layer TPEb may be in contact with the first pad conductive layer TPEa at the opening 116O of the planarization layer 116. The second pad conductive layer TPEb may be formed using the same material and the same process as the conductive layer of the touch electrode TE. The second pad conductive layer TPEb may have a smaller size than the opening 116O of the planarization layer 116.

Referring to FIGS. 23A and 23B, the touch pad electrode TPE includes the first pad conductive layer TPEa and the second pad conductive layer TPEb on the first pad conductive layer TPEa.

The first pad conductive layer TPEa is disposed between the second interlayer insulating layer 115 and the planarization layer 116, and the planarization layer 116 includes the opening 116O through which the first pad conductive layer TPEa is exposed. The opening 116O of the planarization layer 116 may have a smaller size than the first pad conductive layer TPEa.

At least one of the insulating layers of the touch unit 150 is disposed on the planarization layer 116, and the second pad conductive layer TPEb is disposed on the insulating layer of the touch unit 150. For example, the touch buffer layer 151 may be disposed between the planarization layer 116 and the second pad conductive layer TPEb. The touch buffer layer 151 may overlap the opening 116O of the planarization layer 116 and have an opening that is smaller in size than the opening 116O of the planarization layer 116. The second pad conductive layer TPEb may be in contact with the first pad conductive layer TPEa through the opening of the touch buffer layer 151 and the opening 116O of the planarization layer 116.

However, the touch insulation layer 152 may be additionally disposed in addition to the touch buffer layer 151 between the planarization layer 116 and the second pad conductive layer TPEb, or the touch insulation layer 152 may be disposed instead of the touch buffer layer 151, but the present disclosure is not limited thereto.

In this case, the plurality of link lines LL may be disposed under the plurality of touch pad electrodes TPE. The plurality of link lines LL may be composed of various layers of conductive layers. For example, referring to FIG. 22B, the plurality of link lines LL may be disposed between the gate insulating layer 113 and the first interlayer insulating layer 114, and may be connected to another touch pad electrode TPE or another driving pad electrode PE. For another example, referring to FIG. 23B, some of the plurality of link lines LL may be disposed between the gate insulating layer 113 and the first interlayer insulating layer 114, and other some of the plurality of link lines LL may be disposed between the first interlayer insulating layer 114 and the second interlayer insulating layer 115.

Accordingly, in the display device 100 according to an example embodiment of the present disclosure, the touch unit 150 is disposed on the encapsulation layer 140, and various configurations may be disposed to improve the performance of the touch unit 150. For example, the shifting area in which the plurality of first touch lines TL1 are shifted and extended between the plurality of first touch electrodes TE1 may be formed. Therefore, the gap between the contact hole through which the first touch lines TL1 and the first touch electrodes TE1 are connected and the second touch electrodes TE2 may be formed to be constant, and the parasitic capacitance between the first touch lines TL1 and the second touch electrodes TE2 may be configured to be uniform. For example, the delay of the touch signal may be minimized by applying a dual feeding structure that connects two or more touch lines TL to the line of one touch electrode TE or a multi-feeding structure that connects the touch line TL to each of the touch electrodes TE.

For another example, the plurality of pseudo lines PS to which signals having opposite phases to those of touch lines TL are applied may be disposed in the non-display area NA to suppress electromagnetic interference that occurs when transmitting and receiving wireless signals. For example, the ground line GND may be disposed around the plurality of pseudo lines PS to minimize interference between signals of the plurality of pseudo lines PS and the gate driver GD, and to protect other components of the display device 100 including the plurality of pseudo lines PS from static electricity. For example, in the non-display area NA, various lines for driving the display panel PN and various wiring lines for driving the touch unit 150 may overlap each other. Accordingly, the data lines DL and touch lines TL may overlap each other, and the low-potential power line VSSL or the reference line RL, which functions as a shielding film, may be disposed between the touch lines TL and the data lines DL to inhibit their signals from interfering with each other.

Therefore, in the display device 100 according to an example embodiment of the present disclosure, by applying the above configuration, the capacitance variation of the touch electrode TE and the touch line TL, signal interference or electromagnetic interference between the touch unit 150 and other configurations can be reduced, thereby improving the touch sensing performance of the touch unit 150.

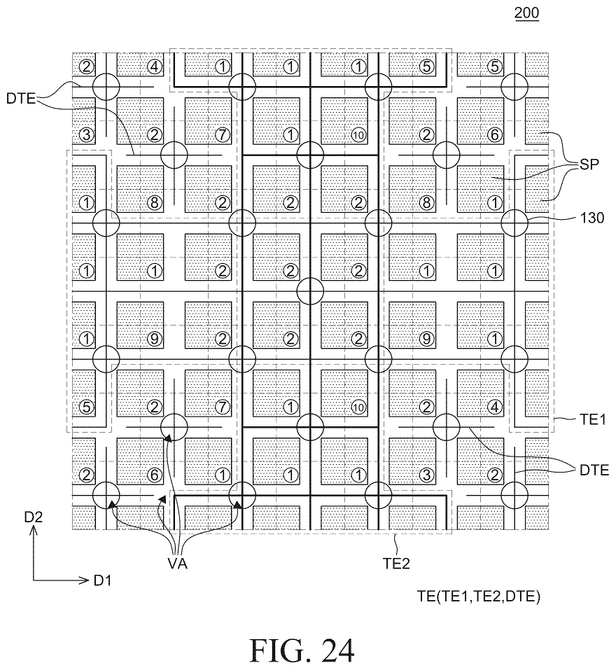

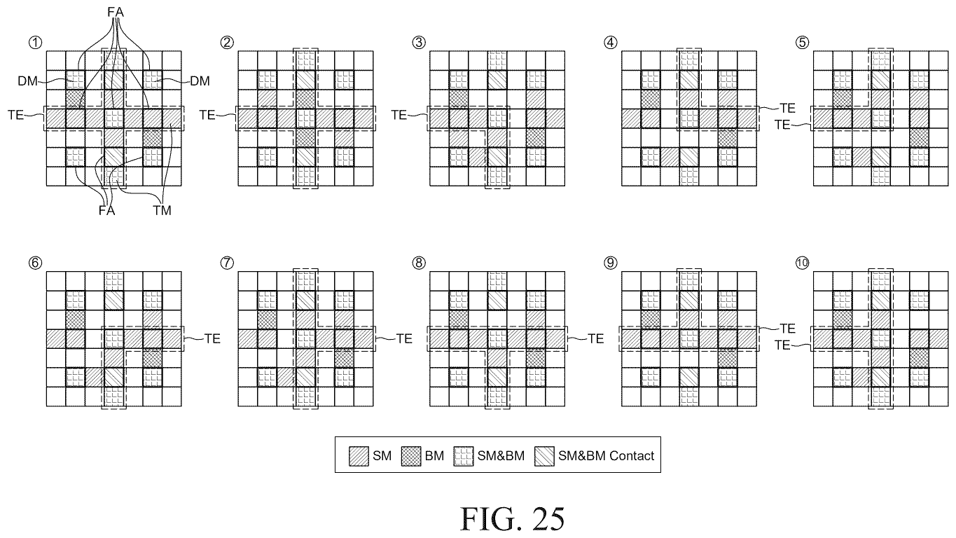

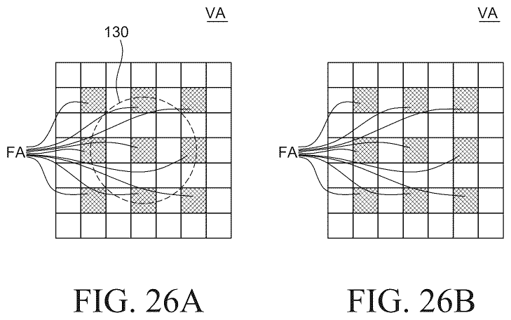

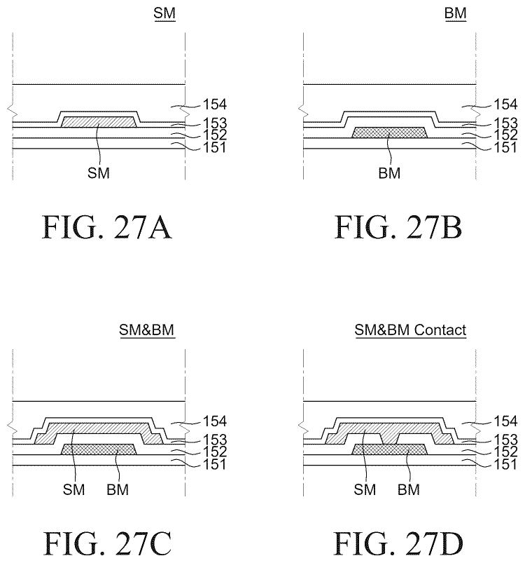

FIG. 24 is a schematic enlarged plan view of a display device according to another example embodiment of the present disclosure. FIG. 25 is an enlarged plan view of a plurality of variable areas of a touch part of a display device according to another example embodiment of the present disclosure. FIGS. 26A and 26B are enlarged plan views for explaining a fixed area of a touch part of a display device according to another example embodiment of the present disclosure. FIGS. 27A to 27D are schematic cross-sectional views of a touch part of a display device according to another example embodiment of the present disclosure. A display device 200 of FIGS. 24 to 27D is substantially identical in configuration to the display device 100 of FIGS. 1 to 23B, except for a touch unit 150. Therefore, repeated descriptions of the identical components will be omitted. In FIG. 24, for the convenience of description, the first touch electrode TE1 and the dummy touch electrode DTE are illustrated as solid lines, and the second touch electrode TE2 is illustrated as a thick solid line.

Referring to FIG. 24, a display device 200 according to another example embodiment of the present disclosure includes a plurality of sub pixels SP, a plurality of spacers 130 disposed between the plurality of sub pixels SP, and a plurality of touch electrodes TE disposed on the plurality of sub pixels SP and the plurality of spacers 130.

The plurality of sub pixels SP may be arranged in a matrix form while forming a plurality of rows and a plurality of columns. Each of the plurality of sub pixels SP may have a rectangular shape. Each of the plurality of sub-pixels SP may overlap the opening of the touch electrode TE.

A plurality of spacers 130 are disposed in an area between the plurality of sub pixels SP. The plurality of spacers 130 may be disposed in some of areas between corners of the plurality of sub pixels SP. For example, one spacer 130 may be disposed in an area between the corners of the four sub-pixels SP. Further, when four sub pixels SP which are opposite to each other with one spacer 130 interposed therebetween are defined as one unit area, the spacer 130 may be further disposed at each of four corners of one unit area. A plurality of spacers 130 may be disposed while forming a lattice pattern. The plurality of spacers 130 may be disposed to cross each other between the spacers 130 disposed in the even-numbered row and the spacers 130 disposed in the odd-numbered row.

Each of the plurality of touch electrodes TE may have a rhombic shape as shown in FIG. 8. Each of the plurality of touch electrodes TE may have a mesh structure. Accordingly, each of the plurality of touch electrodes TE may have an opening overlapping the plurality of sub pixels SP.

The plurality of touch electrodes TE includes a plurality of first touch electrodes TE1 and a plurality of second touch electrodes TE2. The first touch electrodes TE1 of the same line disposed along the first direction D1 among the plurality of first touch electrodes TE1 may be connected to each other to form a line of the first touch electrode TE1. The second touch electrodes TE2 of the same line disposed along the second direction D2 among the plurality of second touch electrodes TE2 may be connected to each other to form a line of the second touch electrode TE2. Further, a line of the first touch electrode TE1 and a line of the second touch electrode TE2 may intersect each other, and FIG. 24 is an enlarged view of an intersection point between a line of the first touch electrode TE1 and a line of the second touch electrode TE2.

A plurality of dummy touch electrodes DTE may be disposed in an area between the plurality of sub pixels SP. Further, the plurality of dummy touch electrodes DTE is disposed between the plurality of touch electrodes TE. For example, a plurality of dummy touch electrodes DTE may be disposed along an area between the first touch electrode TE1 and the second touch electrode TE2. For example, each of the plurality of dummy touch electrodes DTE may have a cross shape in which the touch metal TM in the first direction D1 and the second direction D2 intersect.

Meanwhile, the plurality of touch electrodes TE and the plurality of dummy touch electrodes DTE are disposed along an area between the plurality of sub pixels SP, and at least a part of the plurality of touch electrodes TE may overlap the spacer 130. The touch metal TM, i.e., the bridge metal BM and the sensor metal SM, which constitute the plurality of touch electrodes TE may reflect external light, and the pattern of the touch electrode TE may be partially visible due to the external light reflection. In particular, the amount of reflected light may vary according to the shape of the pattern of the touch electrode TE in the area between the corners of the plurality of sub-pixels SP, and the pattern may be more easily visually recognized due to the deviation of reflected light. In addition, the spacer 130 is disposed in some of the areas between the corners of the plurality of sub-pixels SP. Depending on the pattern shape of the touch electrode TE disposed on the spacer 130, the area of the spacer 130 covered by the touch electrode TE may be different, and the position and the amount of light reflected from the spacer 130 may vary. In addition, a difference in reflected light occurs even in an area in which the spacer 130 is not disposed and only the touch electrode TE is disposed, and in an area in which both the spacer 130 and the touch electrode TE are disposed, so that the pattern of the touch electrode TE can be easily recognized.

Accordingly, in the display device 200 according to another example embodiment of the present disclosure, the shape of the touch metal TM constituting the plurality of touch electrodes TE is similarly configured in the area between the corners of the plurality of sub pixels SP to minimize the deviation of reflected light and prevent the pattern of the touch electrode TE according to the deviation of reflected light from being visually recognized.

The area between the corners of the plurality of sub pixels SP is an area in which the pattern of the touch metal TM is variously changed according to the connection structure of the touch electrode TE. The area between the corners of the plurality of sub pixels SP may be defined as a variable area VA. An area between at least three sub-pixels SP among the plurality of sub-pixels SP may be defined as a variable area VA. For example, each of the plurality of variable areas VA of the touch unit 150 may be an area centered on an area between the four sub pixels SP.

In the display device 200 according to another embodiment of the present disclosure, the common metal pattern may be disposed in the plurality of variable areas VA, such that the overall shape of the touch metal TM of the plurality of variable areas VA may be similarly formed, and the level of reflected light may be similarly formed in each of the plurality of variable areas VA.

Meanwhile, in the touch unit 150 of the display device 200 according to another example embodiment of the present disclosure, the plurality of variable areas VA may be classified into 10 types of first to tenth areas \textcircled{1} to \textcircled{10} depending on the connection structure of the touch electrode TE and the arrangement of the spacer 130.

First, the first area \textcircled{1} and the second area \textcircled{2} are areas in which the spacer 130 is disposed, and the third to tenth areas \textcircled{3} to \textcircled{10} are areas in which the spacer 130 is not disposed. In FIG. 24, the number of each area is written on the upper left of each area. In this case, in the first to tenth areas \textcircled{1} to \textcircled{10}, “SM” hatching is an area in which only the sensor metal SM is disposed among the touch metals TM, “BM” hatching is an area in which only the bridge metal BM is disposed among the touch metals TM, “SM&BM” hatching is an area in which the sensor metal SM and the bridge metal BM overlap each other, and “SM&BM Contact” hatching is a layer in which the sensor metal SM and the bridge metal BM are connected to each other through a contact hole, as shown in FIGS. 25 and 27.

The first area \textcircled{1} is an area where the touch metal TM extending in the first direction D1 and the touch metal TM extending in the second direction D2 cross each other and are connected. For example, the first area \textcircled{1} may overlap only the first touch electrode TE1 or may overlap only the second touch electrode TE2. In the first area \textcircled{1}, the first touch electrode TE1 extending in the first direction D1 and the first touch electrode TE1 extending in the second direction D2 may be connected to each other. In the first area \textcircled{1}, the second touch electrode TE2 extending in the first direction D1 and the second touch electrode TE2 extending in the second direction D2 may be connected to each other. The plurality of first areas \textcircled{1} may be disposed adjacent to each other to form a mesh structure of the touch electrode TE.

The second area \textcircled{2} is an area where the touch metal TM extending in the first direction D1 and the touch metal TM extending in the second direction D2 simply intersect. The second area \textcircled{2} may overlap the crossing area of the first touch electrode TE1 and the second touch electrode TE2 and the dummy touch electrode DTE.

The third to tenth areas \textcircled{3} to \textcircled{10} are areas corresponding to edge portions of the plurality of touch electrodes TE. The third to tenth areas \textcircled{3} to \textcircled{10} are areas that connect the touch metal TM extending to each area in the vertical, left, and right directions with the touch metal TM in the other direction.

For example, the third area \textcircled{3} is an area in which the touch metal TM extending from the left side of the third area \textcircled{3} to the third area 3 and the touch metal TM extending from the lower side of the third area \textcircled{3} to the third area 3 are connected. In the third area \textcircled{3}, the touch metal TM in the first direction D1 and the touch metal TM in the second direction D2 are connected to each other to form a “┐” shape.

The fourth area \textcircled{4} is an area in which the touch metal TM extending from the right side of the fourth area \textcircled{4} to the fourth area \textcircled{4} and the touch metal TM extending from the upper side of the fourth area \textcircled{4} to the fourth area \textcircled{4} are connected to each other. In the fourth area \textcircled{4}, the touch metal TM in the first direction D1 and the touch metal TM in the second direction D2 are connected to each other to form a “└” shape.

The fifth area \textcircled{5} is an area in which the touch metal TM extending from the left side of the fifth area \textcircled{5} to the fifth area \textcircled{5} is connected to the touch metal TM extending from the upper side of the fifth area \textcircled{5} to the fifth area \textcircled{5}. In the fifth area \textcircled{5}, the touch metal TM in the first direction D1 and the touch metal TM in the second direction D2 are connected to each other to form a “┘” shape.

The sixth area \textcircled{6} is an area in which the touch metal TM extending from the right side of the sixth area \textcircled{6} to the sixth area \textcircled{6} is connected to the touch metal TM extending from the lower side of the sixth area \textcircled{6} to the sixth area \textcircled{6}. In the sixth area \textcircled{6}, the touch metal TM in the first direction D1 and the touch metal TM in the second direction D2 are connected to each other to form a “┌” shape.

The seventh area \textcircled{7} is an area in which the touch metal TM extending from the upper, lower, and right sides of the seventh area \textcircled{7} to the seventh area \textcircled{7} is connected to each other. In the seventh area \textcircled{7}, the touch metal TM in the first direction D1 and the touch metal TM in the second direction D2 are connected to each other to form a “├” shape.

The eighth area \textcircled{8} is an area in which the touch metals TM extending from the left, right, and lower sides of the eighth area \textcircled{8} to the eighth area \textcircled{8} are connected to each other. In the eighth area \textcircled{8}, the touch metal TM in the first direction D1 and the touch metal TM in the second direction D2 are connected to each other to form a “ [symbol] ”shape.

The ninth area \textcircled{9} is an area in which the touch metals TM extending from the left, right, and upper sides of the ninth area \textcircled{9} to the ninth area \textcircled{9} are connected to each other. In the ninth area \textcircled{9}, the touch metal TM in the first direction D1 and the touch metal TM in the second direction D2 are connected to each other to form a “⊥” shape.

The tenth area \textcircled{10} is an area in which touch metals TM extending from the upper, lower, and left sides of the tenth area \textcircled{10} are connected to each other. In the tenth area \textcircled{10}, the touch metal TM in the first direction D1 and the touch metal TM in the second direction D2 are connected to each other to form a “┤” shape.

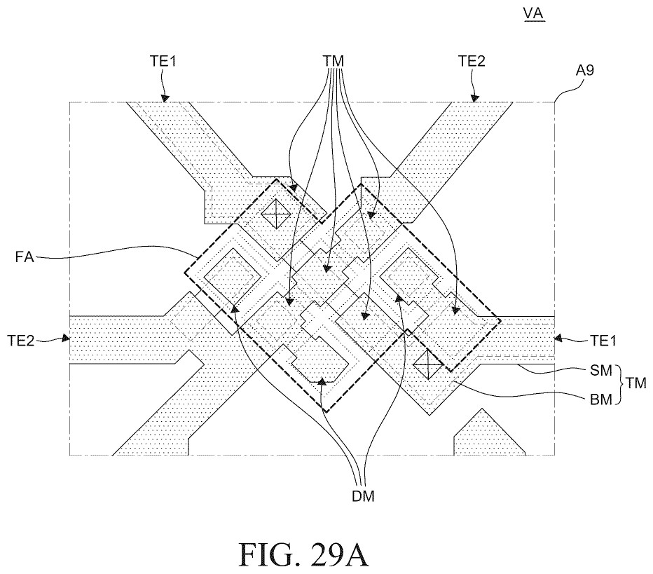

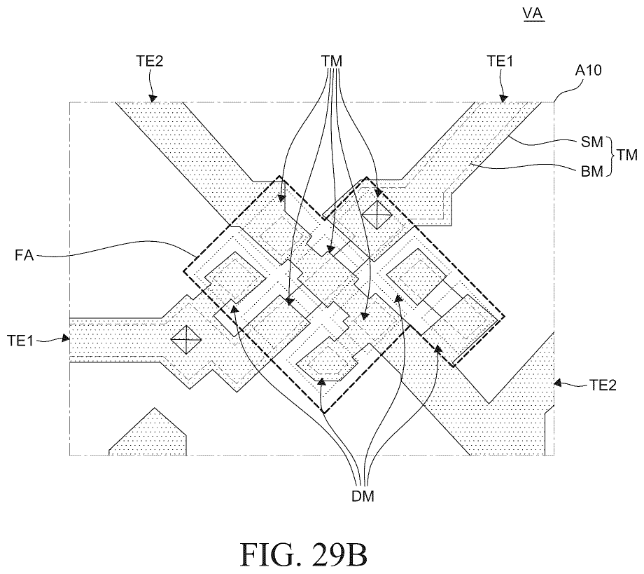

Meanwhile, in the display device 200 according to another example embodiment of the present disclosure, the fixed area FA in which the metal, such as the touch metal TM or a dummy metal DM which will be described with reference to FIGS. 29A and 29B below, is always disposed in the variable area VA is included, such that the level of reflected light in the first to tenth areas \textcircled{1} to \textcircled{10} may be similarly implemented, and pattern visibility due to the deviation of reflected light may be prevented.

Specifically, the plurality of fixed areas FA may be areas corresponding to a central portion and an outer portion of the variable area VA. For example, the plurality of fixed areas FA may be formed of a central portion, four corner portions of the variable area VA, an upper side, a lower side, a left side, and a right side middle portion of the variable area VA, that is, nine parts of the variable area VA. For example, the plurality of fixed areas FA may be formed to correspond to a center point, four vertexes and four midpoints of four sides of a quadrilateral. For example, the plurality of fixed areas FA may correspond to an outer portion of the spacer 130 and a center portion of the spacer 130, as shown in FIGS. 26A and 26B. The plurality of fixed areas FA may be formed in a portion where the touch metal TM of the touch electrode TE is always disposed, a portion that does not interfere with various connection structures of the touch metal TM of the touch electrode TE, and an area outside the opening of the sub pixel SP. Accordingly, the metal is equally disposed in the fixed area FA of each of the plurality of variable areas VA, so that the overall shape of the metal pattern in each area may be similarly formed.

For example, the first area \textcircled{1} is an area in which the touch metals TM in the first direction D1 and the second direction D2 intersecting each other are connected to each other. The touch metal TM substantially functioning as the touch electrode TE in the first area \textcircled{1} may be a cross-shaped touch metal TM crossing the first area \textcircled{1}. In this case, the dummy metal DM may be further formed in the remaining area of the fixed area FA of the first area \textcircled{1}, in which the touch metal TM of the touch electrode TE is not formed, for example, at four corners of the first area 1.

For example, the third area \textcircled{3} is an area in which the touch metals TM extending from the left side and the lower side of the third area \textcircled{3} are connected to each other, and the metal substantially functioning as the touch electrode TE in the third area \textcircled{3} may be the touch metal TM having a “┐” shape. Further, the dummy metal DM may be further formed in each of the remaining areas of the fixed area FA of the third area \textcircled{3}, in which the touch metal TM of the touch electrode TE is not formed, that is, four corner portions, the right side middle portion, and the upper side middle portion.

As another example, the eighth area \textcircled{8} is an area in which the touch metals TM extending from the left, right, and lower sides of the eighth area \textcircled{8} are connected to each other, and the metal substantially functioning as the touch electrode TE in the eighth area \textcircled{8} may be the touch metal TM having a “ [symbol] ” shape. Further, the dummy metal DM may be additionally formed on four corner portions and an upper side middle portion of the fixed area FA of the eighth area \textcircled{8}, which are the remaining areas in which the touch metal TM of the touch electrode TE is not formed.

Accordingly, any one of the touch metal TM or the dummy metal DM is formed in the fixed area FA of the plurality of variable areas VA, so that the shape of the metal pattern in each of the plurality of variable areas VA may be generally similar.

Accordingly, in the display device 200 according to another example embodiment of the present disclosure, the metal patterns having the same shape are commonly disposed in each of the plurality of variable areas VA of the touch unit 150 to reduce the difference in reflected light in each area, so that the touch metal TM is not visually recognized. For example, in the first area \textcircled{1} and the second area \textcircled{2} overlapping the spacer 130, the metal is equally disposed in the fixed area FA to similarly match the amount or shape of the reflected light reflected from the spacer 130 and the touch metal TM. Further, in the third to tenth areas \textcircled{3} to \textcircled{10}, the metal is disposed in the fixed area FA in the same manner to similarly match the amount or shape of the reflected light reflected from the touch metal TM. In addition, even in the third to tenth areas \textcircled{3} to \textcircled{10} in which the spacer 130 is not disposed, the metal is formed in the fixed area FA in the same manner as in the first area \textcircled{1} and the second area \textcircled{2}, such that the overall shape of the metal pattern in the first area \textcircled{1}, the second area \textcircled{2}, and the third to tenth areas \textcircled{3} to \textcircled{10} is similar, and the deviation of the reflected light may be minimized.

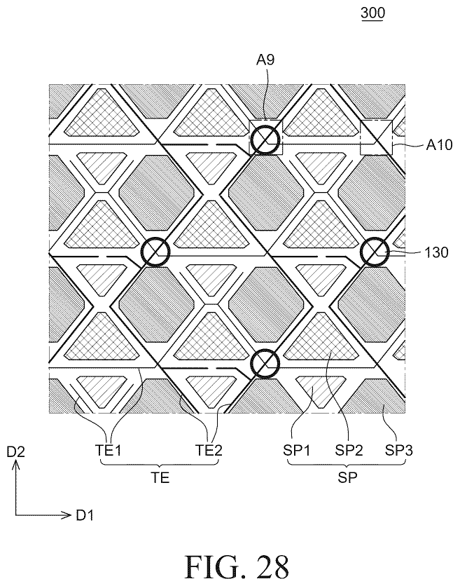

FIG. 28 is a schematic enlarged plan view of a display device according to still another example embodiment of the present disclosure. FIG. 29A is an enlarged plan view of an area A9 of FIG. 28. FIG. 29B is an enlarged plan view of an area A10 of FIG. 28. A display device 300 of FIGS. 28 to 29B has the substantially same configuration as the display device 200 of FIGS. 24 to 27D, except that shapes of the plurality of sub pixels SP and the touch electrode TE are different from shapes of the fixed area FA accordingly, so that a redundant description will be omitted. For convenience of description, in FIG. 28, the first touch electrode TE1 is illustrated as a solid line, and the second touch electrode TE2 is illustrated as a thick solid line.

Referring to FIG. 28, the plurality of sub pixels SP may include a plurality of first sub pixels SP1, a plurality of second sub pixels SP2, and a plurality of third sub pixels SP3. The plurality of first sub pixels SP1 may have an inverted triangle shape and may be arranged in a matrix form while forming a plurality of rows and a plurality of columns. The plurality of second sub pixels SP2 may have a triangular shape and may be alternately disposed with the plurality of first sub pixels SP1 in the second direction D2. The plurality of third sub pixels SP3 has a rhombus shape and may be alternately disposed with the groups of the first sub pixel SP1 and the second sub pixel SP2 in the first direction D1.

The spacer 130 is disposed between the plurality of sub pixels SP. For example, the spacer 130 may be disposed on any one of the left or right sides of each of the plurality of first sub pixels SP1. For example, the spacer 130 may be disposed on any one of the left or right sides of each of the plurality of second sub pixels SP2. For example, the spacer 130 may be disposed on any one of an upper side or a lower side of each of the plurality of third sub pixels SP3. For example, around the area between the plurality of sub pixels SP, two first sub pixels SP1, two second sub pixels SP2, and two third sub pixels SP3 may be disposed in some areas facing each other.

The plurality of touch electrodes TE may be disposed in an area between the plurality of sub pixels SP. The first touch electrode TE1 among the plurality of touch electrodes TE may extend in a zigzag shape along the first direction D1 between the plurality of sub pixels SP. The second touch electrode TE2 among the plurality of touch electrodes TE may extend in a zigzag shape along the second direction D2 between the plurality of sub pixels SP.

In this case, the touch unit 150 may include a plurality of variable areas VA. The plurality of variable areas VA is areas in which the pattern of the touch metal TM is variously changed according to the connection structure of the touch electrode TE. Here, the plurality of variable areas VA is areas centered on areas where two first sub pixels SP1, two second sub pixels SP2, and two third sub pixels SP3 face each other. In each of the plurality of variable areas VA, a touch metal TM forming a first touch electrode TE1 and/or a touch metal TM forming a second touch electrode TE2 may be disposed.

In this case, the fixed area FA in which the metal is always disposed in each of the plurality of variable areas VA is formed to form a shape of the metal pattern of each of the plurality of variable areas VA as a whole similarly.

Referring to FIGS. 29A and 29B, each of the plurality of variable areas VA may include nine fixed areas FA. Among the plurality of fixed areas FA, eight fixed areas FA may be disposed in a V shape, and the other fixed area FA may be disposed to protrude from the right side of the right V shape. The arrangement of the fixed area FA may be determined in consideration of the arrangement structure of the opening portions of the plurality of sub-pixels SP and the touch metal TM. For example, a part in which the touch metal TM of the touch electrode TE is always disposed, a part which does not interfere with various connection structures of the touch metal TM of the touch electrode TE, and a part which does not interfere with the opening of the plurality of sub pixels SP may be configured as the fixed area FA.

For example, referring to FIG. 29A, in some variable areas VA, the touch metal TM of the first touch electrode TE1 extending from the left upper end to the right lower end and the touch metal TM of the second touch electrode TE2 extending from the right upper end to the left lower end cross each other and may be disposed in six fixed areas FA among the plurality of fixed areas FA.

Further, the dummy metal DM may be disposed in the remaining fixed area FA in which the touch metal TM is not disposed. For example, the dummy metal DM may be disposed on each of the left, lower, and right sides based on the intersection point of the first touch electrode TE1 and the second touch electrode TE2. The dummy metal DM on the left side of the intersection point may be composed of an island-shaped sensor metal SM and a bridge metal BM, and the dummy metal DM on the lower side of the intersection point may be composed of a sensor metal SM extending from the second touch electrode TE2. The dummy metal DM on the right side of the intersection point may be composed of a sensor metal SM extending from the first touch electrode TE1 and an island shaped bridge metal BM.

Referring to FIG. 29B, in another variable area VA, the touch metal TM of the second touch electrode TE2 extending from the upper left end to the lower right end and the touch metal TM of the first touch electrode TE1 extending from the upper right end to the lower left end may cross each other. The touch metals TM of the first touch electrode TE1 and the second touch electrode TE2 intersecting each other may be disposed in five fixed areas FA having an X shape, among the plurality of fixed areas FA.

Further, the dummy metal DM may be disposed in the remaining fixed area FA in which the touch metal TM is not disposed. For example, the dummy metal DM may be disposed in the fixed areas FA on the left, lower, and right sides based on the intersection point of the first touch electrode TE1 and the second touch electrode TE2 and the fixed area FA disposed on the rightmost side of the plurality of fixed areas FA. The dummy metal DM on the left side of the intersection point may be composed of a sensor metal SM extending from the first touch electrode TE1 and a bridge metal BM having an island shape, and the dummy metal DM on the lower side of the intersection point may be composed of a sensor metal SM extending from the second touch electrode TE2 and a bridge metal BM having an island shape. The dummy metal DM on the right side of the intersection point may be composed of an island-shaped sensor metal SM and a bridge metal BM, and the dummy metal DM of the rightmost fixed area FA may be composed of a sensor metal SM extending from the second touch electrode TE2 and an island-shaped bridge metal BM.

Accordingly, in the display device 300 according to still another example embodiment of the present disclosure, the fixed area FA in which the metal is commonly formed is formed in the variable area VA in which the pattern of the touch metal TM of the plurality of touch electrodes TE is variously changed so that the difference in reflected light according to the difference in the shape of the metal pattern of the variable area VA may be minimized. At least one of the touch metal TM and the dummy metal DM may be disposed in the fixed area FA of the plurality of variable areas VA, such that a common metal pattern may be disposed in the plurality of variable areas VA. Accordingly, the overall shape of the metal pattern in the plurality of variable areas VA may be similarly formed, and the deviation of reflected light and thus pattern visibility may be prevented.

The example embodiments of the present disclosure can also be described as follows:

According to an aspect of the present disclosure, a display device includes a substrate on which a plurality of sub-pixels is formed, an encapsulation layer disposed on the substrate, and a touch part disposed on the encapsulation layer. The touch part includes a plurality of variable areas disposed between at least three sub-pixels among the plurality of sub-pixels, a plurality of fixed areas disposed in each of the plurality of variable areas, a plurality of touch electrodes disposed in each of the plurality of variable areas between the plurality of sub-pixels and the plurality of variable areas, and a dummy metal disposed in each of the plurality of variable areas. Any one of the touch metal and the dummy metal is disposed in each of the plurality of fixed areas.

The touch part may further include a touch buffer layer disposed on the encapsulation layer, a bridge metal disposed on the touch buffer layer, a touch insulating layer disposed on the bridge metal, a sensor metal disposed on the touch insulating layer, a touch passivation layer disposed on the sensor metal, and a touch protective layer disposed on the touch passivation layer. The touch metal and the dummy metal may be formed of a bridge metal and a sensor metal.

According to another feature of the present disclosure, the plurality of touch electrodes may include a first touch electrode and a second touch electrode, and the first touch electrode and the second touch electrode may cross each other in a variable area of some of the plurality of variable areas.

According to another feature of the present disclosure, the plurality of touch electrodes may be configured by a touch metal extending in a first direction and a touch metal extending in a second direction different from the first direction, and in some variable areas among the plurality of variable areas, the touch metal extending in the first direction and the touch metal extending in the second direction may cross each other and be connected.

According to another feature of the present disclosure, the touch metal of the plurality of touch electrodes may be disposed in a partial area of the plurality of fixed areas, and the dummy metal may be disposed in the remaining area of the plurality of fixed areas.

The display device may further include a spacer disposed between the substrate and the encapsulation layer. The spacer may overlap some of the plurality of variable areas.

According to another feature of the present disclosure, some of the plurality of fixed areas may overlap the spacer, and the rest of the plurality of fixed areas may correspond to the outer portion of the spacer.

According to another feature of the present disclosure, in each of the plurality of variable areas, only the bridge metal or the sensor metal may be disposed, or the bridge metal and the sensor meta may overlap each other or may be connected to each other.

A display device according to another example embodiment of the present disclosure includes a substrate including a display area and a non-display area, a planarization layer disposed on the substrate, a light emitting element disposed on the planarization layer, an encapsulation layer disposed on the light emitting element and having an edge disposed in the non-display area, and a touch part disposed on the encapsulation layer and the substrate. The touch part includes a touch buffer layer on the encapsulation layer, and a touch insulating layer on the touch buffer layer, and the touch buffer layer and the touch insulating layer extend to an area outside the encapsulation layer to cover an edge of the encapsulation layer.

The display device may further include a plurality of dam members disposed in the non-display area and disposed to surround the display area. The encapsulation layer may include a first inorganic encapsulation layer, an organic encapsulation layer on the first inorganic encapsulation layer, and a second inorganic encapsulation layer on the organic encapsulation layer. The organic encapsulation layer may be disposed in an area inside the plurality of dam members, and the first inorganic encapsulation layer and the second inorganic encapsulation layer may cover the plurality of dam members.

The display device may further include a pad unit disposed in the non-display area and a plurality of link lines extending from the pad unit to the display area. Some of the plurality of link lines disposed on the plurality of dam members may have a width of a portion overlapping the plurality of dam members greater than a width of a portion spaced apart from the plurality of dam members.

The touch part may further include a plurality of first touch electrodes disposed to form a plurality of rows and a plurality of columns, a plurality of second touch electrodes disposed to cross the plurality of first touch electrodes, and a plurality of dummy touch electrodes disposed between the plurality of first touch electrodes and the plurality of second touch electrodes.

The touch part may further include a plurality of first touch lines connected to each of the plurality of first touch electrodes, and a plurality of second touch lines connected to each of the plurality of second touch electrodes.

According to another feature of the present disclosure, some of the plurality of first touch lines may be shifted from the column direction to the row direction in a shifting area between the plurality of first touch electrodes adjacent to each other and extend in the column direction.

The display device may further include an encapsulation layer and a plurality of pseudo lines disposed on the substrate and surrounding the display area, and a plurality of ground lines disposed on the encapsulation layer and the substrate. A part of the plurality of pseudo lines may be disposed in an area outside the encapsulation layer, the rest of the plurality of pseudo lines may be disposed on the encapsulation layer, and the plurality of ground lines may be disposed adjacent to the plurality of pseudo lines.

The display device may further include a gate driver which is disposed between the substrate and the planarization layer and includes a scan signal driver and an emission signal driver, and a width of a ground line which overlaps the gate driver among the plurality of ground lines may be larger than a sum of a width of the scan signal driver and a width of the emission signal driver.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure.

What is claimed is:

1. A display device, comprising:
a substrate;
a plurality of sub-pixels;
an encapsulation layer disposed on the substrate; and
a touch part disposed on the encapsulation layer,
wherein the touch part includes:
a plurality of variable areas disposed between at least three sub-pixels among the plurality of sub-pixels;
a plurality of fixed areas disposed in each of the plurality of variable areas;
a plurality of touch electrodes disposed in each of the plurality of variable areas between the plurality of sub-pixels and configured by a touch metal; and
a dummy metal disposed in each of the plurality of variable areas, and
wherein at least one of the touch metal and the dummy metal is disposed in each of the plurality of fixed areas.

2. The display device of claim 1, wherein the touch part further comprises:
a touch buffer layer disposed on the encapsulation layer;
a bridge metal disposed on the touch buffer layer;
a touch insulating layer disposed on the bridge metal;
a sensor metal disposed on the touch insulating layer;
a touch passivation layer disposed on the sensor metal; and
a touch protective layer disposed on the touch passivation layer,
wherein the touch metal and the dummy metal are formed of the bridge metal and the sensor metal.

3. The display device of claim 2, wherein the plurality of touch electrodes includes a first touch electrode and a second touch electrode, and
the first touch electrode and the second touch electrode cross each other in a variable area of at least some of the plurality of variable areas.

4. The display device of claim 2, wherein the plurality of touch electrodes is configured by the touch metal extending in a first direction and the touch metal extending in a second direction different from the first direction, and
in at least some variable areas among the plurality of variable areas, the touch metal extending in the first direction and the touch metal extending in the second direction cross each other.

5. The display device of claim 2, wherein the touch metal of the plurality of touch electrodes is disposed in a partial area of the plurality of fixed areas, and the dummy metal is disposed in the remaining area of the plurality of fixed areas.

6. The display device of claim 2, further comprising:
a spacer disposed between the substrate and the encapsulation layer,
wherein the spacer overlaps a part of the plurality of variable areas.

7. The display device of claim 6, wherein some of the plurality of fixed areas overlaps the spacer, and the rest of the plurality of fixed areas corresponds to an outer portion of the spacer.

8. The display device of claim 2, wherein in each of the plurality of variable areas, only the bridge metal or the sensor metal is disposed, or the bridge metal and the sensor meta overlap each other or are connected to each other.

9. A display device, comprising:
a substrate;
a display area and a non-display area;
a planarization layer disposed on the substrate;
a light emitting element disposed on the planarization layer;
an encapsulation layer disposed on the light emitting element and having an edge disposed in the non-display area; and
a touch part disposed on the encapsulation layer and the substrate,
wherein the touch part includes:
a touch buffer layer on the encapsulation layer; and
a touch insulating layer on the touch buffer layer, and
wherein the touch buffer layer and the touch insulating layer extend to an area outside the encapsulation layer to cover the edge of the encapsulation layer.

10. The display device of claim 9, further comprising:
a plurality of dam members disposed in the non-display area and disposed to surround the display area,
wherein the encapsulation layer includes:
a first inorganic encapsulation layer;
an organic encapsulation layer on the first inorganic encapsulation layer; and
a second inorganic encapsulation layer on the organic encapsulation layer, and
wherein the organic encapsulation layer is disposed in an area inside the plurality of dam members, and the first inorganic encapsulation layer and the second inorganic encapsulation layer cover the plurality of dam members.

11. The display device of claim 10, further comprising:
a pad unit disposed in the non-display area; and
a plurality of link lines extending from the pad unit to the display area,
wherein at least some of the plurality of link lines disposed on the plurality of dam members has a width of a portion overlapping the plurality of dam members greater than a width of a portion spaced apart from the plurality of dam members.

12. The display device of claim 9, wherein the touch part further includes:
a plurality of first touch electrodes disposed to form a plurality of rows and a plurality of columns;
a plurality of second touch electrodes disposed to cross the plurality of first touch electrodes; and
a plurality of dummy touch electrodes disposed between the plurality of first touch electrodes and the plurality of second touch electrodes.

13. The display device of claim 12, wherein the touch part further includes:
a plurality of first touch lines connected to each of the plurality of first touch electrodes; and
a plurality of second touch lines connected to each of the plurality of second touch electrodes.

14. The display device of claim 11, wherein at least some of the plurality of first touch lines are shifted in a row direction and extended in a column direction in a shifting area between the plurality of first touch electrodes adjacent to each other in the column direction.

15. The display device of claim 9, further comprising:
a plurality of pseudo lines disposed on the encapsulation layer and the substrate and disposed to surround the display area; and
a plurality of ground lines disposed on the encapsulation layer and the substrate, wherein a part of the plurality of pseudo lines is disposed in an area outside the encapsulation layer,
wherein the rest of the plurality of pseudo lines is disposed on the encapsulation layer, and
the plurality of ground lines is disposed to be adjacent to the plurality of pseudo lines.

16. The display device of claim 15, further comprising:
a gate driver which is disposed between the substrate and the planarization layer and includes a scan signal driver and an emission signal driver,
wherein a width of a portion of a ground line which overlaps the gate driver among the plurality of ground lines is larger than a sum of a width of the scan signal driver and a width of the emission signal driver.
